(19) United States
(12) Patent Application Publication
(10) Pub. No.: US 2013/0284578 A1
(43) Pub. Date: Oct. 31, 2013

(54) INFORMATION CARRIER AND SYSTEM FOR ACQUIRING INFORMATION

(71) Applicants: Matthias Foerster, Dresden (DE); Andre Kreutzer, Mittweida (DE); Jan Thiele, Chemnitz (DE); Sascha Voigt, Bernsdorf (DE); Thoralt Franz, Zwoenitz/Bruenlos (DE)

(72) Inventors: Matthias Foerster, Dresden (DE); Andre Kreutzer, Mittweida (DE); Jan Thiele, Chemnitz (DE); Sascha Voigt, Bernsdorf (DE); Thoralt Franz, Zwoenitz/Bruenlos (DE)

(73) Assignee: PRINTECHNOLOGICS GMBH, Chemnitz (DE)

(21) Appl. No.: 13/825,159

(22) PCT Filed: Sep. 20, 2011
(86) PCT No.: PCT/EP2011/066337

§ 371 Date: Jul. 3, 2013

Related U.S. Application Data
(60) Provisional application No. 61/384,478, filed on Sep. 20, 2010.

(51) Int. Cl. H03K 17/96

(52) U.S. Cl. CPC H03K 17/9622
USPC 200/600; 156/241

(57) ABSTRACT

The invention describes a capacitive information carrier in which at least one electrically conductive touch structure is arranged on an electrically non-conductive substrate. The invention also comprises a system and method for acquiring information, consisting of a capacitive information carrier, a capacitive area sensor, a contact between the two elements and interaction which makes the touch structure of the information carrier evaluable for a data processing system connected to the area sensor and can trigger events associated with the information carrier.

The invention describes a capacitive information carrier in which at least one electrically conductive touch structure is arranged on an electrically non-conductive substrate. Furthermore, the invention comprises a system and a method for acquiring information, consisting of a capacitive information carrier, a capacitive area sensor, a contact between both elements and interaction which makes the touch structure of the information carrier evaluable for a data processing system connected to the area sensor and can trigger events associated with the information carrier.

In the meaning of the invention, an information carrier is in particular a medium for storing, imaging, filing and/or assigning information.

In the meaning of the invention, a capacitive area sensor is in particular a physical interface for acquiring electrical capacitances and/or capacitance differences within subareas of a defined area. Devices containing area sensors comprise, for example, smartphones, cell phones, displays, tablet PCs, tablet notebooks, touchpad devices, graphics tablets, television sets, PDAs, MP3 players, trackpads and/or capacitive input devices. Such an area sensor, for example, can also be an integral part of input devices as a touchscreen, touchpad or a graphics tablet. Touchscreens are also known as tactile screens or touch-sensitive screen. Such input devices are used, amongst others, in smartphones, PDAs, touch displays or notebooks.

Known readers or apparatuses for acquiring and reading capacitive information represent individual devices which have this and only this purpose. Disadvantages of the readers or apparatuses disclosed in the prior art are that for the individual applications, always separate capacitive readers have to be available and they are often connected to data processing media via an interface. Because of this, distribution and acceptance of readers is relatively poor and purchasing the readers is associated with additional costs. Moreover, linking real printed information with digital information is very difficult to implement. One possibility are barcodes which can be acquired by means of suitable scanners or cameras and can call up digital contents. The disadvantage of known barcodes is that they are associated with the system-typical handicaps and, e.g.: information can be copied at will, they visually take up space on products or advertising media, they are difficult to individualize in sufficiently good quality, a direct visual contact between code an acquisition unit is required, which due to dirt, scratches, light conditions etc. make a correct acquisition and readout difficult or can completely obstruct it. Previously known capacitive data carriers always bridge within a reader between (at least) one reading and one receiving electrode. Depending on the presence or absence of a capacitive structure, a logic “1” and/or “0” is recognized.

The prior art shows a plurality of possibilities to produce information carriers by means of printing technologies or other coating methods, which information carriers can be read by means of suitable reading methods or readers (e.g., U.S. Pat. No. 3,719,804). The probably most common information carriers produced in such a manner are barcodes in the embodiment as a one-dimensional barcode or, for example, as two-dimensional variants. They are acquired with suitable optical scanners and, if required, further processed via adequate data processing systems.

The printing technologies and coating technologies for producing such features likewise continue to develop. Thus, EP 1 803 562 describes a method for transferring imaging layers from one carrier film or transfer film onto print sheets in a sheet-processing machine. Here, an adhesive is applied in a first application station and is brought together with a transfer film in a further coating station, and material from the transfer film is applied onto the print sheet by means of adhesion. In the process of this, a transfer gap is formed in the application station and the transfer film is placed along the surface of a press roll and onto a print sheet with the side that is coated with transfer material, and is fed under pressure together with the print sheet through said transfer gap so that the imaging layers are transferred in areas covered with adhesive from the carrier film onto the print sheet so as to adhere thereon. With this, barcodes and alphanumeric information can be readily applied.

Furthermore, in the prior art, flat printed materials are disclosed in U.S. Pat. No. 5,818,019, U.S. Pat. No. 3,719,804, U.S. Pat. No. 4,587,410 and US 2006/0118612, which materials allow a secure verification or validation of data. This can make sense for drugs and their packaging but also for lottery tickets. The printed information ensure, e.g., authentication or serve as validity check. Also, capacitively readable information carrier are known, amongst others, from the applications U.S. Pat. No. 3,719,804 (permanent information store) and U.S. Pat. No. 4,587,410 (parking system). In the last-mentioned example, processing and changeability of capacitive structures for a parking meter are illustrated. By means of a mechanical unit, the capacitive structure in the reader is successively changed and thus its “inner value” is changed. Individualization of the structures is not provided. The complete system is an autarkic system without interaction with other systems or data processing or data storage. In U.S. Pat. No. 3,719,804, the production possibilities by means of printing technologies such as, for example, screen printing, flexo printing and gravure printing are listed. The description refers to liquid processible materials which are suitable for printing processes. This involves all problems that are associated with such liquid processible inks. The inks that meet the requirements are very expensive, contain solvents, have a limited shelf live and cause process-related problems. Individualization is carried out by means of separation techniques of the applied conductor tracks. The reading method is greatly position-dependent and is associated with a fixed reading position of the information carrier in the reader.

In summary, the solutions for information carriers proposed in the prior art have a plurality of problems. For example, they are not inexpensive enough for high-volume applications and, due to their complex structure, are only partially recyclable (RFID systems), can sometimes easily be copied (barcodes), generate high costs by attaching them onto the end product, and are difficult to process, or cannot be processes at all, with printing technologies (chip cards).

Based on this prior art, it is an object of the present invention to provide an easily implementable capacitive information carrier for a capacitive area sensor for triggering at least one event.

An event in the meaning of the invention designates in particular something that triggers, preferably within applications, an action and thus a change of state. These events can be, for example, user inputs or system events. The events are preferably triggered on devices which carry the area sensor themselves, for example, smartphones, cell phones, displays, tablet PCs, tablet notebooks, touchpad devices, graphics tablets, television sets, MP3 players, trackpads and capacitive input devices, without being limited thereto.

The object is achieved by the independent claims. Preferred exemplary embodiments arise from the sub-claims.

It was completely surprising that with the capacitive information carrier according to the invention, the system according to the invention as well as the use of information carriers and systems and with the method according to the invention for acquiring information, the disadvantages of the prior art could have been overcome.

Thus, a capacitive information carrier is provided wherein on an electrically non-conductive substrate at least one electrically conductive substrate is arranged as a touch structure. The touch structure comprises preferably at least one touch point, one coupling surface and/or one conductor path.

In the meaning of the invention, a coupling surface is in particular an electrically conductive area on the substrate. The coupling surface represents a preferred variant of the information carrier according to the invention which, for example, makes it possible to couple to external electrical capacitances which are not part of the touch structure and thus to increase the effective electrical capacitance of the touch structure of the information carrier. As a result, the information carrier can be read in a particular secure and reliable manner. This can take place when a person touches or approaches it and also through coupling by an object.

Conductor paths preferably consist of an electrically conductive layer and preferably establish an electrical connection between two or a plurality of subareas.

Advantageously, in a preferred embodiment, the substrate consists of a plastic, a paper, a card board, a wooden material, a composite material, glass, ceramics, fabrics, leather or a combination thereof. The substrate is in particular an electrical non-conductive substance which is preferably flexible and has a low weight. Translucent or opaque substrates can be used. Preferred plastics comprise in particular PVC, PETG, PV, PETX, PE and synthetic papers.

It is preferred that the electrically conductive layer is a metal layer, a layer containing metal particles, a layer containing electrically conductive particles, an electrically conductive polymer layer, or a layer of at least one combination of these layers. Electrically conductive particles are in particular soot or graphite particles. In the meaning of the invention, polymers designate in particular a substance that is composed of a collective of chemically uniformly structured macromolecules (polymer molecules) which, however, usually differ with regard to the degree of polymerization, molar mass and chain length. The polymers are preferably electrically conductive. In such substances with uniform polymers, all macromolecules are preferably structured identically and differ only in term of their chain length (degree of polymerization). Such polymers can be designated as polymer homologs. Polymers can be selected from the group comprising inorganic polymers, metallo-organic polymers, fully or partly aromatic polymers, homopolymers, copolymers, biopolymers, chemically modified polymers and/or synthetic polymers. Particularly preferred are polymers selected from paraphenyle, polyacetylene, polypyrrole, polythiophene, polyaniline (PANI) and PEDOT. Thus, the information carrier can be produced in a cost-effective manner by means of a mass-production method.

According to the invention, a touch structure is in particular a layer of conductive material applied in structured manner. Through the combination according to the invention of these two properties, electrical conductivity and structure, it was surprisingly possible to achieve a specific interaction of the touch structure with capacitively effective areas.

Since touch point, conductor path and coupling surface can preferably consist of the same or similar electrically conductive materials, an information carrier can preferably be produced using only one technological method. As a result, the information carriers can be easily and economically implemented as a mass-produced article. In a preferred embodiment of the invention, it can be provided that on the substrate a touch structure is arranged that has at least one coupling surface which is connected to at least one touch point via at least one conductor path, and/or a portion of the touch point is a coupling surface.

In the meaning of the invention, the touch structure can be designated in particular as a signature or signet. Through the combination according to the invention of these two properties, electrical conductivity and structure, it was surprisingly possible to achieve a specific interaction of the touch structure with capacitive effective areas of an area sensor. Thus, the structure of the touch structure is evaluable for a data processing system that is connected to the area sensor. Advantageously, the applied touch structure can be alterable in certain areas in terms of its structuring by means of additive and/or subtractive methods, preferably by inkjet methods and particularly preferred by laser methods.

In a preferred embodiment, the touch structure is a printed layer on the substrate. It was completely surprising that the touch structure can be applied onto a substrate by means of a printing method. It is preferred that the information carrier is produced by means of a printing method, preferably an additive and/or subtractive method, known to the person skilled in the art. This is a significant advantage over the prior art since hereby, the information carrier can be produced using mass-production methods. Advantageously, the touch structure can be implemented in an easy and economically advantageous manner with an additive or subtractive method.

However, it is also preferred that the touch structure is transferred onto the substrate by means of a transfer method. Preferably, applying the substrate onto the touch structure can take place through transfer methods known per se; preferably, this concerns here transfer film methods and particularly preferred a cold film transfer method. Such methods are known to the person skilled in the art and he/she knows that it is possible by means of a printing method to apply a substance (such as, e.g., a touch structure) onto a substrate in a structured manner, in particular in certain areas. Here, the substrate is not covered over the entire surface by the touch structure, but the touch structure is applied only on certain areas of the substrate. Of course, other methods for a structured application of a layer can also be used.

Furthermore, a capacitive information carrier is provided which is produced using a transfer film method, the method comprising the following steps:
a. providing a transfer film on a roll, wherein the transfer film comprises a carrier film and placed thereon, at least in certain areas, an electrically conductive transfer layer,
b. providing an electrically conductive substrate,
c. providing an adhesive,
d. structured application of the adhesive according to c) onto the substrate and/or the transfer film,
   wherein on the electrically non-conductive substrate, at least in certain areas, an electrically conductive layer is arranged as a touch structure. It is preferred that at least the touch structure is covered with a further layer.

The information carrier preferably comprises an electrically non-conductive substrate onto which an adhesive is applied at least in certain areas, as well as an at least single-layered, electrically conductive layer applied congruent thereto through adhesion on the adhesive, wherein the adhesive and the electrically conductive layer are layers applied by a transfer method, preferably by a transfer film method, and particularly preferred by a cold film transfer method, and the electrically conductive layer is configured as a touch structure, and at least the touch structure is covered with a further layer.

Structuring the electrically conductive layer takes place in particular via the adhesive that is preferably an electrically conductive adhesive. It is preferred that the adhesive is applied in an arrangement or layout directly onto the substrate (printing substrate) and is subsequently guided in contact with the transfer film. Advantageously, applying the adhesive and also bringing the substrate and the transfer film together can be carried out in a machine. The transfer film itself consists of at least two layers, a transferable layer (=transfer layer) and a further carrier material (the carrier film) which carries said layer. The connection of the two layers is configured such that transferring the transfer layer onto the substrate by means of the adhesive is possible without problems so that accordingly, the adhesion of the adhesive to the substrate and the transfer layer has to be higher than the cohesion of the transfer layer and the adhesion of the transfer layer on the carrier material. Once the material transfer is completed, the substrate material contains the adhesive applied in a structured manner and likewise the transfer material as a transfer layer covering said adhesive, wherein the transfer material is now structured as well. This can be facilitated with the aid of pressure, temperature, mechanical auxiliary means such as embossing stamps, contact pressings etc. In this manner, an information carrier can be provided which, due to its layout and the material properties of the transfer material, results in a capacitive readable structure which can be determined in a suitable reader or can interact with an area sensor. It is preferred that at least the layer forming the touch structure is covered at least in certain areas with a further layer, wherein said layer preferably is a paper layer, a film layer, a paint layer, a lacquer layer and/or combinations thereof. In the meaning of the invention, the further layer can also be designated as cover layer. The cover layer can advantageously be used as protection or for obliteration of the touch structure of the information carrier. In a preferred variant, this cover layer can also be implemented as a cover plate. The cover plate can consist of rigid or flexible materials.

In a further preferred embodiment, on an electrically non-conductive substrate, at least one electrically conductive touch structure is arranged that simulates the arrangement and/or properties of fingertips. The additional property of the touch structure of simulating the arrangement and/or properties of fingertips is particularly advantageous here because such a structure can be evaluated in a simple manner by a data processing system that is connected to an area sensor, and it can be better processed through software.

In the meaning of the invention, a capacitive area sensor can in particular be designated as a touchscreen.

In the prior art, such a touchscreen comprises in particular an active circuit, the touchscreen, which is connected to a structure of electrodes. These electrodes are usually divided into transmitter and receiver electrodes. The touch controller controls the electrodes preferably in such a manner that a signal is transmitted between in each case one or a plurality of transmitter electrodes and one or a plurality of receiver electrodes. In the idle state of the touchscreen, the signal remains constant, for example. The purpose of a touchscreen described in the prior art is in particular recognizing fingers and their position on the surface of the touchscreen. Here, introducing a finger effects that the signal between the electrodes is changed. Usually, the signal strength is reduced because the finger placed thereon absorbs a portion of the signal from the transmitter electrode, and therefore a weaker signal arrives at the receiver electrode.

An advantageous property of the touch structure is the conductivity thereof. If instead of a finger, a preferred information carrier having the touch structure is brought in contact with an area sensor, the conductive areas preferably cause the same effect as a finger. However, the conductive structure is structured area by area because, on the one hand, the effect that is comparable to introducing a finger is to be maximized at certain positions, in particular the touch points, so as to be recognizable for the touch controller in the best possible manner. Thus, advantageously, the touch structure becomes evaluable for a data processing system connected to the area sensor.

In a further preferred embodiment, at least one electrically conductive touch structure simulating the arrangement and/or properties of fingertips is arranged on an electrically non-conductive substrate. The touch structure comprises at least one touch point, one conductor path and/or one coupling surface. It is preferred that the combination of at least one or a plurality of touch points in a touch structure simulates the arrangement and/or properties of fingertips. In the meaning of the invention it is possible with the touch structure, comprising preferably at least one coupling surface, particularly preferred at least one conductor path and more preferred at least one touch point, to carry out, similar to a finger, an input on the area sensor. For this reason, the preferred embodiment of the invention can be described by the fact that the touch structure simulates the properties of fingertips, wherein this preferably designates the property of the touch structure that the touch structure, like a finger, can perform an input on an area sensor. This additional property of the touch structure of simulating the arrangement and/or properties of fingertips is particularly advantageous here because such a structure can be evaluated in a simple manner by a data processing system that is connected to an area sensor, and it can be better processed through software.

In this connection, a touch point suitably simulates the properties of fingertips by structuring the conductive area on the information carrier. It is known to a person skilled in the art that an input on a touchscreen or an area sensor can be carried out by means of one or a plurality of fingers (single- or multi-touch). The technology of area sensors and the principles of input or, respectively, through which of the properties of a finger an input takes place, are also known to the person skilled in the art. For example, apart from the electrical properties of the finger (e.g., conductivity), density, pressure of the input, or distance from the area sensor can also influence the input. By structuring the conductive area, the preferred system achieves the same effect on an area sensor as a finger, namely an input on a position on the area sensor, which position is defined by the conductive areas of the information carrier. Thus, the person skilled in the art would be able without major experimental efforts to implement the touch structure of the information carrier in such a manner that the properties of fingers or fingertips are simulated, and an input on an area sensor can be achieved with the electrically conductive areas of the information carrier.

In one example, without being limited thereto, of a preferred information carrier in interaction with a so-called touchscreen having an electrode arrangement in the form of a grid, a suitable structuring of the touch point, for example, is a circle with a diameter of from 1 to 20 mm, preferred 4 to 15 mm, and particularly preferred 6 to 10 mm. Since a touchscreen is suitable for determining the position of fingertips, a touch point of an information carrier can be determined by the touchscreen in the same manner. The touchscreen or the area sensor is advantageously not able to differentiate if the input was carried out by the touch structure of an information carrier or by a finger.

It can be preferred to apply a plurality of touch structures on the information carrier according to the invention. Advantageously, shape, orientation, quantity, alignment, distance and/or position of subareas of the touch structure can be used for storing information.

Advantageously, according to a further preferred embodiment, the electrically conductive material is a printed layer on the substrate. Thus, the layer can be implemented with an additive method in a simple and economically favorable manner. Such methods are known to the person skilled in the art. Of course, all other methods for applying an electrically conductive layer in a structured manner can also be used.

According to a further preferred embodiment, the electrically conductive layer is implemented by using a subtractive method, wherein areas of layers are removed. For this purpose, known ablation methods using etching or laser are used. In the latter case, the material to be removed is vaporized through the action of the laser beams. Of course, further methods can also be used.

It was completely surprising that the information carrier or a group of information carriers and/or the system according to the invention can be used in many fields of economic life. These fields comprise, for example, playing cards, collector cards, postage stamps, franking, postal charges, goods logistics, goods tracking, access, tickets, access to closed areas, virtual contents, marketing applications, customer retention, lottery and gambling activities, member identifications, season tickets, payment applications, certificates of authenticity, certificates, counterfeit protections, copy protections, signatures, delivery notes, bank statements, package leaflets, objects within computer games, music/video/e-book downloads, bonus cards/programs, device controllers or gift cards, without being limited thereto.

It can also be preferred that the information carrier is connected to an article, or the article itself serves as a substrate. Designated as an article in the meaning of the invention is in particle a thing, a subject or an object. An article is preferably selected from the group comprising packaging, tableware, printing products, clothing, furniture, documents, toys, consumer items, food, semi-finished products, machine parts, construction materials, disposable and reusable containers and/or electrical devices. In principle, non-flat articles can also be a direct carrier of an information carrier (the article assumes the function of the substrate), or an indirect carrier in that the information carrier can be attached to the article or applied thereon. Attaching or applying, for example, can be carried out in a self-adhesive manner or by means of other known bonding technologies or auxiliary materials, for example a label on textiles.

Advantageously, at least one information carrier is in contact at least in certain areas with at least one area sensor. For this, at least one electrically conductive layer is applied in certain areas on a substrate, wherein at least one area of the electrically conductive layer is a subarea. The subarea or subareas in the meaning of the invention are also designated as touch structure. The shape, orientation, quantity, alignment, distance and/or position of the touch structure or the subareas thereof preferably form the information so that by positioning the information carrier on the area sensor at least in certain areas or via a relative movement of at least one area of the information carrier with respect to the area sensor, at least one event is triggered. In the meaning of the invention, positioning the information carrier on the area sensor in certain areas means that in particular one area of the information carrier is in contact with at least one area of the area sensor.

The information carrier is preferably brought in contact with the area sensor in such a manner that at least one event is triggered by the area sensor.

In the meaning of the invention, bringing in contact means that in particular between the information carrier and the area sensor, there is no clearance. This means, the information carrier is preferably in physical contact with the area sensor. However, it can also be preferred that there is no direct contact between the information carrier and the area sensor and that approaching is already sufficient for triggering an event. When approaching, there is a preferred distance between the information carrier and the area sensor of greater than 0 cm to 2 cm.

Accordingly, the invention relates also to a system, comprising at least one capacitive information carrier and at least one capacitive area sensor, wherein between the information carrier and the area sensor a contact or approach takes place and through this, a capacitive interaction is achieved. Through the capacitive interaction, the touch structure of the information carrier becomes evaluable for a data processing system connected to the area sensor and thus can trigger events associate with the information carrier. In the meaning of the invention, an area sensor also designates a touchscreen.

Through this capacitive interaction, preferably, an event can be triggered on the device carrying the area sensor. The event, in turn, triggers actions such as, for example, activating and/or terminating an application (a program), changing numerical values and/or texts, manipulating graphics, changing databases or obtaining access to information technology services, without being limited thereto.

It is preferred that the area sensor comprises at least one capacitive display and that the device containing the area sensor is selected from the group comprising smartphones, cell phones, displays, tablet PCs, tablet notebooks, touchpad devices, graphics tablets, television sets, PDAs, MP3 players, trackpads and/or capacitive input devices, without being limited thereto. A capacitive area sensor, for example, can also be an integral part of input devices as a touchscreen, touchpad or a graphics tablet. Touchscreens are also known as tactile screens or touch-sensitive screen. Such input devices are used, amongst others, in smartphones, PDAs, touch displays or notebooks. An area sensor does not necessarily have to be located in front of a display. For example, said area sensor can also be configured and used as a keyboard. Besides a click function, a drag-and-drop operation can also be carried out. Furthermore, it is also possible to use a plurality of simultaneous touches in the form of a so-called “multi-touch” for rotating or scaling displayed elements, for example. The area sensor is preferably implemented here as so-called projected capacitive touch technology (PCT). Variants of the PCT technology are, for example, “mutual capacitance” and “self capacitance”, which can be implemented as mutual-capacitance screen and self-capacitance screen.

The information carriers according to the invention are advantageously characterized in that therewith, a connection to a device having an area sensor can be implemented. The area sensor preferably acts analogous to a capacitive reader, but without being dependent on fixed, predefined conductor paths or reading electrodes as they are currently limitingly known from the prior art (U.S. Pat. No. 3,719,804—Permanent information store). Through the information carriers according to the invention, an extension of the range of functions of devices containing capacitive area sensors opens up. As a result, for example, access to information is made easier and/or the use of the devices is simplified (especially for physically handicapped, disabled or elderly persons) and/or new applications are enabled, without being limited thereto.

Preferably, information in the form of the touch structure, which can be configured as a subarea, is stored on the information carrier. Upon contact or when the information carrier approaches the area sensor, the information can be read via the latter, wherein the capacitance is in particular partially changed.

The touch structure forming the information, i.e., the subareas of an area, consists of an electrically conductive material. The person skilled in the art recognizes according to the disclosure of the present invention that the touch structure consists of corner points and/or fill areas defined by curves, for example, rectangles, circles or similar figures. The spatial relations of the subareas to each other (orientation, quantity, alignment, distance and/or position) and/or the shape of the subareas preferably represent the information. When positioning the information carrier at the area sensor, the touch structure is interpreted, for example, as finger input so that from the subareas of the touch structure, the encoded information can be determined, for example, in the form of a binary coded number, without being limited thereto. However, an information carrier can be directly interpreted as information carrier, or, respectively, the context of the use of the information carrier determines in particular its specific information. Positioning can also be carried through a movement of the information carrier relative to the area sensor. It is preferred that the area sensor, in a movement relative to the information carrier, progressively receives complete or partial information from the information carrier. In this connection it is also possible that different events are generated in dependence on the positions of the information carrier with respect to the area sensor. Essential for this is, for example, the direction of movement or the residence time of the information carrier with respect to the area sensor.

Advantageously, the information carrier can be configured as a simple, signed, or encoded information carrier. Thus, the information carrier is suitable as key for the authorized use of certain amounts of data or hardware, wherein communication can take place via a known data network such as, for example, the internet. It can also take place via a device which comprises the area sensor.

As summarized hereinafter, an action is that which is preferably triggered by an event.

In connection with a device containing an area sensor, the information carrier is
a simple information carrier for triggering actions in the program sequence on the device itself,
a signed information carrier for triggering actions in the program sequence of the device and/or an external data processing system which can be connected via a data network,
an encoded information carrier which is decoded by the program sequence of the device and/or an external data processing system and triggers actions in the program sequence of the device or the external data processing system.

According to a further preferred embodiment, at least two touch structures each having at least one associated coupling surface are located on the substrate. With this arrangement, at least two events can be triggered in that the user, for example, touches the respective associated coupling surface. Through this, for example, yes/no decisions can be triggered by the user via the information carrier.

Advantageously, a plurality of information carriers can be read in combination, in particular next to each other and/or one above the other and/or in chronological succession. Hereby it is surprisingly possible to store complex information on an information carrier, wherein the information carrier, for example, is printed on card board and/or paper. The information carrier surprisingly connects print media with digital media, which was not possible up to now in such a manner.

It is further preferred that the information carrier is assigned to a dataset in a data processing system and the dataset remains constant. In a preferred embodiment, the information carrier is assigned to a dataset in a data processing system and the dataset is changed. This can take place, for example, by using the information carrier and/or by means of time, without being limited thereto.

Advantageously, the information carrier can be used in such a manner that the information carrier in connection with an area sensor can be assigned via the touch structure to an action of the data processing system or can trigger said action. This action applies in particular to non-networked data processing systems and particularly preferred to networked data processing systems.

The invention relates also to the use of a capacitive information carrier for acquiring information. Here, at least one capacitive area sensor and at least one capacitive information carrier is provided, wherein the information carrier has an electrically non-conductive substrate which comprises at least one electrically conductive touch structure. The at least one information carrier is brought in contact with the at least one area sensor, wherein the contact can be static and/or dynamic. Here, a static contact describes that in particular in the moment of the evaluation of the information carrier, no movement or an insignificant movement relative to the area sensor takes place. In contrast, a dynamic contact describes that in particular a relative movement during the evaluation of the information carrier may take place. According to the invention, said contact can also comprise an approach. Through said contact, a capacitive interaction is triggered, wherein through the capacitive interaction, information is transferred from the information carrier to the area sensor.

The area of the electrically conductive layer—the touch structure—preferably consists of subareas. In particular, the shape, orientation, quantity, alignment, distance and/or position of the subareas form the information of the information carrier so that upon contact of the information carrier with the area sensor, an event is triggered. In this context, the program sequence of a device can be controlled with the area sensor. The subareas, i.e., the touch structure, preferably consist of corner points and/or fill areas defined by curves, for example, rectangles, circles or similar figures.

The subareas, for example, can be 8 mm circles. Thus, on an area sensor with a width of 50 mm and a height of 75 mm at a resolution of 163 ppi (pixel per inch), the subareas virtually have a size of approximately 50×50 pixels. The subareas with a size of 8 mm can be divided 54-times in an arrangement of 6×9 on the area sensor. This results in the following:

The position of the subareas can be determined up to one half of their diameter; the number of possible positions thereby doubles per axis; however, in each case one position at the margin is omitted. Therefore, (6*2−1)×(9*2−1), thus 11×17 positions are distinguishable.

In an extreme case, an occupied position blocks nine possible adjacent positions. Thus, in the case of five used positions, 5×9=45 positions of the 17×11=187 possible positions are omitted. Thus, 142 free positions are left. The free positions as subareas are subject to the binomial coefficient.

Thus, the formula

$$( \begin{matrix}142 \\ 5\end{matrix} )$$

results in the possible arrangements of the subareas. In this case, 448072338 different arrangements of subareas are possible. This number can be represented as a binary number with 29 digits. This results in at least 2²⁸ possible arrangements, and 28 bit of data can be represented.

For the number of subareas of from 5 to 18, the following table results:

| | |
|---|---|
| 5 * 9 = 45 | 142 choose 5 <2²⁹ |
| 6 * 9 = 54 | 133 choose 6 <2³³ |
| 7 * 9 = 63 | 124 choose 7 <2³⁷ |
| 8 * 9 = 72 | 115 choose 8 <2⁴⁰ |
| 9 * 9 = 81 | 106 choose 9 <2⁴² |
| 10 * 9 = 90 | 97 choose 10 <2⁴⁴ |
| 11 * 9 = 99 | 88 choose 11 <2⁴⁵ |
| 12 * 9 = 108 | 79 choose 12 <2⁴⁶ |
| 13 * 9 = 117 | 70 choose 13 <2⁴⁶ |
| 14 * 9 = 126 | 61 choose 14 <2⁴⁵ |
| 15 * 9 = 135 | 52 choose 15 <2⁴³ |
| 16 * 9 = 144 | 43 choose 16 <2³⁸ |
| 17 * 9 = 153 | 34 choose 17 <2³² |
| 18 * 9 = 162 | 25 choose 18 <2¹⁹ |

Accordingly, twelve subareas result in a maximum of 45 bit of date which can be represented according to this example. This means:
with a maximum of five subareas, up to a maximum of 28 bit can be accommodated on an information carrier 1, and
with twelve subareas, up to a maximum of 45 bit can be accommodated on an information carrier 1.

By diminishing the subareas, the amount of data can be significantly increased.

The invention also relates to a method for recognizing a capacitive information carrier which preferably is installed on a computer-based system having a touchscreen. Said method comprises the provision of a capacitive baseline, the generation of a current signal when the capacitive information carrier is brought in contact with the touchscreen or approaches the latter. By comparing the capacitive baseline with the generated signal, an event is triggered.

As soon as a computer-based system having a touchscreen recognizes the capacitive information carrier (through contact or approach), an event is triggered. However, it can also be preferred that the touchscreen only recognizes the information carrier and forwards the information to a computer which, correspondingly, triggers an event. The touchscreen can be an integral part of a monitor comprising monochrome monitors, color monitors (CGA, EGA, VGA, super VGA), LCD, CRT, LED, OLED or plasma monitors. However, it can also be advantageous if the touchscreen is not integrated in the monitor and rather is implemented as a separate component. For example, the touchscreen can be configured as a touchpad or trackpad. The touchscreen preferably forwards the information received from the information carrier to a data-processing device, whereby preferably an event is triggered.

The event, in turn, preferably triggers an action. The action, can be, for example, registering on a computer or a computer network, or the access to a restricted area, loading a computer profile with associated personal settings of a computer, access to web contents, starting a computer program, opening and/or closing a document, viewing a menu, carrying out further actions, encoding and/or decoding a document, or operating an input and/or output device. It can also be preferred that a plurality of information carriers have to be combined in order to get access to access-restricted areas, for example. Here, the necessary information carriers can be distributed to different persons, which meets a high safety standard. A plurality of information carriers can also be combined to form a related sequence so that an event is triggered only upon completing the entire sequence. The information carrier can be used, for example, for triggering an event which outputs personal data, bank data or credit card data. This can be advantageous in particular in the banking sector or retailing sector.

The information carrier can also be used for advertising purposes, for example, by using it as a lottery ticket that establishes access to a homepage on which a decision is made on potential winnings. The information carrier can also be given away or sold as a promotion article together with other articles. By means of the information carrier, the recipient can gain access to promotional information or product information. For example, by means of the information carrier, the recipient can in particular open websites that contain a user manual for a purchased product.

The operating system of the computer or the device that has a touchscreen preferably includes a program, in particular a recognition program, which comprises the method for recognizing a capacitive information carrier. Operating systems are well known and comprise OS/2, DOS, UNIX, Linux, Windows, Windows Mobile, Android-based systems, iOS, Mac OS, Darwin etc. The recognition program can be implemented in the operating system or can be implemented as a separate software. Preferably, the recognition program is stored in the ROM or RAM.

The recognition program can also be stored in an external storage medium, comprising CD-ROM, PC-CARD, disc, magnetic storage medium or network component. It can also be advantageous if the recognition program is stored in the touchscreen itself (e.g. in the firmware). The recognition program is preferably accessible to a user, which program can be displayed on the touchscreen. The user can change settings and/or can determine a region on the screen on which the information carrier preferably is recognized. In principle, the recognition program consists of commands which recognize a contact with the information carrier and inform the operating system about it and/or trigger an event.

The computer is preferably a PC (personal computer), comprising a desktop computer, laptop or smartphone. However, the computer can also be an integral part of a public computer system such as, for example, public computer terminals, cash machines (ATM), POS (point-of-sale machines), industrial computer systems, game consoles, slot machines, ticket vending machines, booking machines, service stations and many more.

The touch structure applied onto the information carrier can advantageously comprise simple and/or complex structures. For example, circles, squares, rectangles, points, triangles, logos, symbols, text or the like can be applied thereon. Furthermore, it is preferred to implement the structure as a binary code or embossed printing. The structure can also be an indication of the action to be carried out. For example, the structure can have the shape of a key which indicates that with the information carrier or, respectively, the structure, an access is opened. The structure can also be applied onto an existing card, e.g., a credit card. The touchscreen can be an integral part of any computer system that is able to transmit, receive and/or store. The computer system can be a PC, laptop, handheld computer, IBM-, Windows- or Apple-compatible computer.

Hereinafter, the use of the information carrier shall be explained by means of examples, but without being limited thereto:

### Use of the Information Carrier for Purchasing Products or Goods

The information carrier can be used for purchasing goods or products. For example, a store or a kiosk can accommodate a device having a touchscreen which is accessible to a customer. The customer has an information carrier with which he/she can be identified in the store or kiosk via the device. By using the information carrier, the customer can identify himself/herself at the device and, for example, can view already purchased goods and personal data. The identification takes place through the information carrier that has to be brought in contact with the area sensor of the device—the touchscreen—or has to approach the touchscreen. In the meaning of the invention, the touchscreen is in particular also designated as area sensor.

Advantageously, a device having a touchscreen is connected via the internet or further computers or devices to a network through which information can be exchanged. For example, the costumer can have a credit that can be retrieved by means of the information carrier, wherein via the network, the actual amount of the credit can be determined. After loading the personal data and the already purchased goods, the customer can decide whether he/she wants to order the same goods again. This is in particular advantageous if this concerns purchasing a newspaper or buying basic foods which are purchased on a regular base. For example, via the information carrier, the customer can also gain access to a sample of a book or to a trial subscription of a newspaper or a magazine. In this manner, an information carrier in the form an advertising flyer can be delivered to the buyer of a magazine. The buyer can read the information carrier by means of his/her smartphone and gains access to information about a certain product. It is up to the buyer to order the product already or to take a look at the product on the webpage of the product provider. Also, the buyer is informed about the providers and the locations of the providers.

Advantageously, the information carrier can also be printed in a magazine or a newspaper and can comprise, for example, advertisement of a travel agent. An interested person can bring a device having an area sensor in contact with the advertisement—the information carrier—and receives information about the offered trip. If the interested person wants to book the trip, this can be done directly via the device, e.g., a smartphone. For this purpose, a program on the smart phone contacts via the internet a further program of the travel agent who is given the personal data and credit card data of the interested person. If the interested person agrees to the proposed price, he/she can book the trip. He/she then receives the booking confirmation by mail or digitally. Also, through a similar procedure, flights can be booked which are advertised in a newspaper or a magazine.

It can also be of advantage that an information carrier is offered to a visitor of a restaurant and the visitor, via the information carrier and a device having a touchscreen (e.g. a smartphone), can access a webpage of the restaurant on which the recipes of the dishes offered in the restaurant are available. Advantageously, it is also possible to order the goods necessary for the recipes directly online. Moreover, information about ingredients of the dishes can be displayed to the visitor, which is in particular of importance for allergy sufferers.

Also, by means of the received information carrier, the visitor can be informed about special events that take place in the restaurant. The events or other information received can advantageously be stored directly in the device, for example the smartphone and, e.g., can be entered in a calendar. Also, the automatic entry of the restaurant into a contact database of the smartphone can be initiated by the visitor since the contact data are available to the visitor through the information carrier.

Advantageously, for purchasing goods or products, no personnel is required. The goods or products can be order by the customer and can be delivered to the customer later. It is also possible that the information carrier triggers an action through which for example, the information carrier receives a product directly. For example, a candy vending machine or a newspaper vending machine having a touchscreen can be operated by the information carrier. The product purchased by the customer is displayed on the touchscreen and the customer can confirm or decline the purchase. For this, for example, two areas on the touchscreen can be provided to the customer for actuation. The purchase is triggered only after the customer has confirmed the purchase. After the purchase, the customer receives on the touchscreen a summary of the purchase which can be stored on the storage medium of the device.

It can also be preferred that the information carrier is attached on the purchased product or the packaging of the product. Through the information carrier, the customer who has purchased the product gains access to product-specific information material or accessories. The customer only has to bring the information carrier in contact with the touchscreen or advance it toward the touchscreen, whereby an action is triggered through which, for example, a certain webpage in the internet is displayed to the customer, a certain program is started, or a video is shown to the customer.

The information carrier can be printed onto packaging of foodstuff, for example. A buyer uses, for example, his/her smartphone so as to read the information of the information carrier and thus gains access to specific information about the purchased foodstuff, comprising recipes, ingredients and/or cooking instructions (video and/or audio).

It can also be preferred to purchase goods by means of the information carrier via a television set, preferably a capacitive touchscreen. The television set preferably has an area sensor, preferably a capacitive touchscreen. The information carrier can be brought in contact with the touchscreen of the television set or can be advanced toward the latter. For example, a product can be purchased from shopping channels in that the customer identifies himself/herself by means of the information carrier, and hereby the product is purchased.

The information carrier can preferably be used for triggering programs. For example, after attending a concert, a person can acquire an information carrier. At home, the information carrier is brought by the person in contact with a device having a touchscreen or is advanced toward it, whereby an event and an action is triggered. Advantageously, the device has internet access and allows the person to access a webpage on which products of the previously visited concert are offered. The person also can watch a video of the concert visited on the webpage, wherein the person has first to identify himself/herself with the information carrier. Only through the information carrier, the person gains access to restricted areas on the webpage.

### Use of the Information Carrier as a Supplement to a Printed Product

The information carrier can also be printed as a part of a textbook or can be enclosed in it. The textbook contains exercises which, e.g., a student can solve. After solving the problems, the student can bring a device having a touchscreen, e.g., a smartphone, in contact with the information carrier in the textbook or can advance it toward the information carrier and thereby gains access to the solutions which, for example, are available on a webpage with restricted access. Also, videos or audio files which help the student during studying can be accessible in this manner.

It can also be preferred that the information carrier is enclosed to a book or is printed thereon. Via the information carrier and via a touchscreen, the buyer of the book gains access to a webpage on which further books of the author are offered and, possibly, a trailer of a planned film version of the book can be watched. Prior to buying the book, an interested person can bring the information carrier on the book in contact with his/her smartphone, whereby a free sample is displayed on the smartphone to said person. Thus, the interested person has the possibility to read a sample of the book prior to the purchase.

The information carrier can also be printed on the packaging of a DVD or Blu-ray or can be enclosed thereto. The information carrier enables the buyer to access a webpage which comprises further information about the purchased movie (e.g. information about actors or additional material). Advantageously, the information carrier can be printed on the packaging of a DVD, a Blu-ray or a video game. By means of a smartphone, a potential buyer can read the information carrier and possibly can test without obligation a sample of the product to be purchased.

The information carrier can also be obtained as a supplement with the purchase of a magazine or a newspaper and can establish the access to programs or web contents by means of a device having a touchscreen.

### Use of the Information Carrier as a Coupon

The information carrier can also be used as a coupon or discount card. The information carrier can be sent or distributed as advertisement to potential customers by an enterprise. The recipient can redeem the information carrier at a special terminal or similar devices having a touchscreen, which are preferably located within the enterprise. For example, the customer can select for a certain amount of money a product of the enterprise and can pay with the information carrier by bringing the information carrier in contact with the touchscreen or by advancing it toward the touchscreen, thereby triggering an event. The information carrier, for example, triggers an action similar to a coupon, wherein the customer can use the coupon for paying the product.

Advantageously, the information carrier can also be used in the internet as a coupon. For example, the customer can purchase products in the internet and can trigger the payment action by bringing the information carrier in contact with a device having a touchscreen. The information carrier can also be used as a coupon for a music download or the like.

It can also be of advantage if a plurality of information carriers are collected by a person and a coupon is activated only through the combination of a predefined number of information carriers. For example, a plurality of information carriers can be combined with a touchscreen in such a manner that only a certain number of information carriers trigger an event or an action. The individual information carriers are displayed on the touchscreen as part of a geometric figure so that it is visible for the person how many information carriers are still required for completing the figure. A completed figure can preferably be stored on the device having the touchscreen and, if applicable, can be exchanged with other persons who also collect information carriers. The devices can communicate with each other via a network or other communication channels, comprising Bluetooth, infrared etc.

### Use of the Information Carrier as a Ticket

It can also be preferred that the information carrier is used as a ticket. The information carrier can be used, for example, as a cinema ticket. The information carrier can be sent to a person as part of an advertising campaign or the person receives the information carrier as a supplement to a newspaper. Of course, the person can also purchase the information carrier directly at a point of sale. The information carrier, for example, enables the person to access a cinema, in particular to a certain movie. At the entrance of the cinema, the person only needs to bring the information carrier in contact with a touchscreen, wherein the touchscreen is an integral part of a device in the cinema. Through the contact or by approaching the touch screen, an event or an action is triggered and preferably, a ticket for the movie is issued to the person.

Preferably, the information carrier can already be printed on a product or a ticket. The information carrier can also be printed onto packaging. It is preferred to use a transfer method, preferably a transfer film method, as a printing method. Thus, for example, the information carrier can be printed on a packaging of a CD. Through the information carrier, a buyer of the CD gains access to further pieces of music or to merchandising products of the performer.

### Use of the Information Carrier as a Business Card

The information carrier can also be used as a business card. The owner of an information carrier can store personal data on the information carrier and can forward the information carrier to other persons. The persons simply advance the information carrier to a touchscreen, thereby triggering an action. The action can be, for example, that the private homepage of the owner of the information carrier is opened. The personal data are preferably stored directly on the device having a touchscreen and are transferred into the contact database, for example.

### Use of the Information Carrier as a Key

It can also be preferred that the information carrier is used as a key. This means, the owner gains access to restricted areas only by means of the information carrier. The owner identifies himself/herself, for example, at a door by means of the information carrier, whereby on the touchscreen, which is attached to the door, an action is triggered through which opening of the door is possibly achieved.

Advantageously, it is also possible to use a plurality of information carriers for accessing restricted areas. For example, access to high-security areas may only be permitted by using two different information carriers that have been issued to two different persons. Also, triggering of important programs can be restricted in such a manner that the programs can only be started by using at least two different information carriers which preferably were distributed to two different persons.

Use of the Information Carrier with a Smartphone

Advantageously, the information carrier can also interact with smartphones. For this, the information carrier is brought in contact with the capacitive touchscreen or is advanced toward the latter, thereby triggering an event on the smartphone which, in turn, can start a program. The smartphone preferably displays the identity of the information carrier and advantageously offers the user a selection of different steps. Thus, the user can trigger the program immediately or only at a later time. This can be particularly advantageous if establishing an internet connection is not possible, and the connection is to be established at a later time. The user then receives a message on the touchscreen that currently there is no internet connection, wherein the user can select if a connection shall be established immediately or only later. Advantageously, information about the information carrier is also displayed to the user, which information is stored in the storage of the smartphone, if required. Also, the information carrier can communicate commands to the smartphone which, in turn, can be implemented through a program. Thus, for example, a program can execute a hyperlink and can contact a certain internet webpage directly or through a web service.

In this connection, the information carrier can also be used as a certificate or authentication means that is needed to permit the user access to certain websites or programs. For example, the information carrier may contain a password that is transmitted to the device by means of the touchscreen, and the access to restricted contents is only possible by providing said password. Smartphones can be used for sending and receiving e-mails. If an e-mail is decoded, it cannot be read upon receipt. Only after a code is entered, the e-mail becomes readable. It is also possible to use the information carrier as an authentication means. An information carrier is delivered to a potential recipient of e-mails. Upon receipt of a decoded e-mail, the recipient is requested to advance the information carrier to the touchscreen, whereby the information on the information carrier becomes readable. The read information is checked, and as soon as a positive validation took place, the e-mail can be read by the recipient.

### Use of the Information Carrier as a Shopping Guide

The information carrier can be printed on products or goods. If a customer is interested in the products, but no expert advice on the products is possible, the customer can bring the information carrier in contact with his/her smartphone or another device that has a capacitive touchscreen or can advance it to said device. The information carrier triggers an event or action through which, for example, the webpage of the product manufacturer is displayed on the smartphone. Here, the customer can find out further information about the product. The information can be present in the form of text, as video or audio file and, for example, can comprise the use of the product, specific accessories, or other things.

It can also be preferred that the information carrier is distributed as an advertising flyer by a store. An interested person can combine the received information carrier with a device which comprises an area sensor. The information carrier triggers an event or an action so that it is displayed on the smart phone to the interested person how he/she gets from his/her location to the store. At the same time, he/she can receive a discount card for the store via the information carrier.

### Use of the Information Carrier as a Payment Means

The information carrier, for example, can be printed on the packaging of products or goods. If a customer is interested in the product, he/she can view information about the product by means of the information carrier, as illustrated above. However, it is also possible to purchase the product directly. The information carrier, for example, transfers important data of the product, e.g. the price, to a smartphone. The smartphone advantageously has access to the internet and has a program that allows purchasing the product via the internet. After the information carrier has been brought in contact with the smartphone and the smartphone has all the information needed for the purchase, the purchase can be completed. The program sends the information about the product and the customer via the internet to a further program which processes the purchase. The data of the customer such as address and bank data and/or credit card data are communicated to this program. After the purchase has been confirmed, this is signalized to the customer and he/she can take the product. Confirmation of the successful purchase, which is also sent to the smartphone, can serve as evidence for the purchase and can be used as confirmation at the exit of the department store, for example.

Use of the Information Carrier in Combination with a Microchip

It can also be advantageous if a microchip is arranged on the information carrier. Advantageously, the microchip can actively or passively transmit electronic information such as, for example, serial numbers or codes, to an electronic receiver. A user of the information carrier, for example, can identify himself/herself at a touchscreen by means of the information carrier, wherein the device receives further information from the microchip. However, it can also be advantageous if a barcode is applied onto the information carrier. The barcode can be applied onto the information carrier in the form of a two-dimensional code and can also serve for encoding a serial number, for example. The barcode, e.g., can be a matrix code, a QR code or an Aztec code. The microchip and/or the barcode can also be used for identifying the information carrier.

### Use of the Information Carrier as a City Guide

The information carrier can be attached on points of interest. For example, it can be attached on a monument or a building or on a board. A tourist who preferably has a smartphone or another device having an area sensor can view the board during a tour and, if necessary, can bring his/her smartphone in contact with the information carrier. This triggers an action on the smartphone, through which action, a webpage is displayed to the tourist on which he/she can find additional information about the point of interest. The information can be present as a text or video, for example. If needed, merchandising products of the point of interest can also be acquired via the internet, which products are sent directly to the home address of the tourist.

It can also be advantageous if in a certain district, which is regularly visited by tourists, an information carrier is attached in a central position on an object. After the tourist has brought his smartphone in contact with the information carrier, he/she receives information about the district. The information can be provided, for example, through a program or the internet and can comprise video and audio data. The tourist is informed about restaurants, stores, points of interest and, where applicable, the discount actions thereof.

### Use of the Information Carrier as a Security Feature

The information carrier can advantageously be applied as a security feature on documents or identification cards. For this, the information carrier can be printed onto the substrate—such as, e.g., a banknote—wherein the information carrier on the banknote can be visible or invisible. For verifying the banknote, said banknote can be brought in contact with a reader or an area sensor, whereby the information carrier is preferably capacitively read, and through this, the authenticity of the banknote can be verified. The information carrier is able to verify not only the authenticity of bills, but it can also be used for counting and determining the value of the bills. For example, with a reader or an area sensor (e.g. a touchscreen), visually impaired persons can determine the value of the bills in that the information carrier encodes the corresponding value, and said value is read out by the reader or the area sensor. It is also possible to integrate the information carrier in credit cards or identification cards in order to very authenticity.

The invention is now exemplary described with reference to figures, however, without being limited thereto; in the figures:

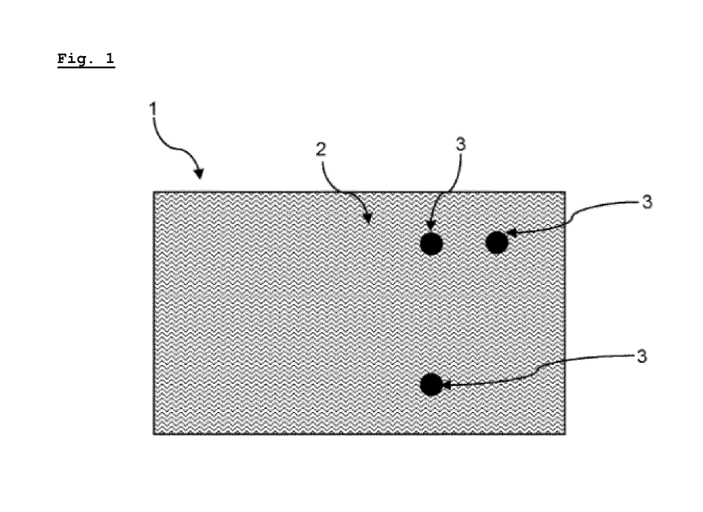

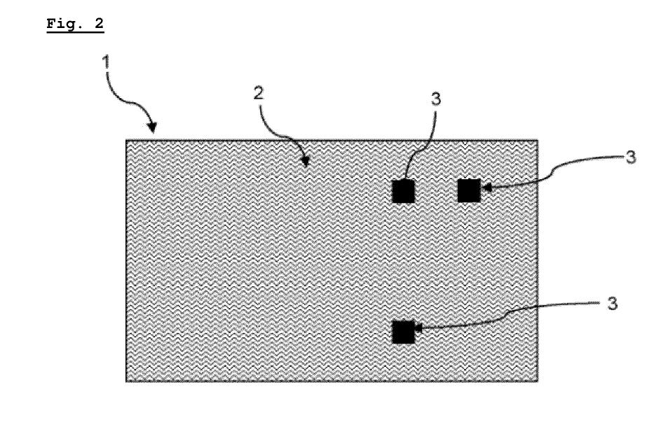

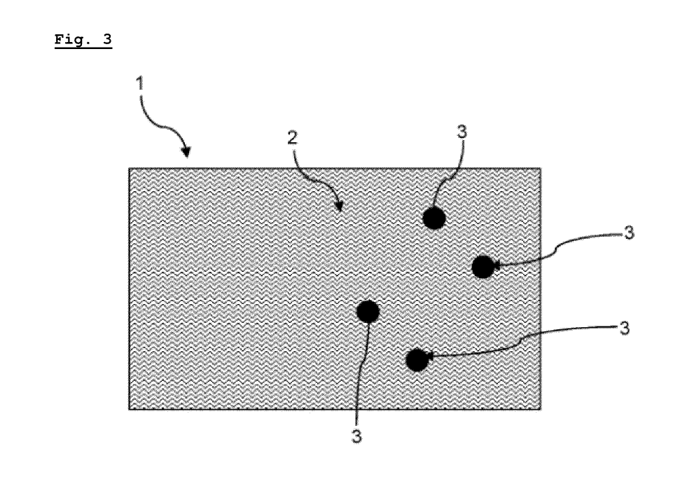

FIG. 1 to FIG. 4 show top views of preferred configurations of an information carrier,

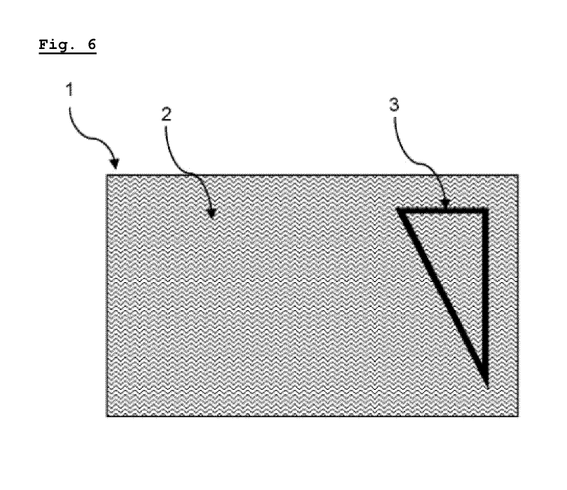

FIG. 5a and FIG. 5b show information carriers in a sectional illustration,

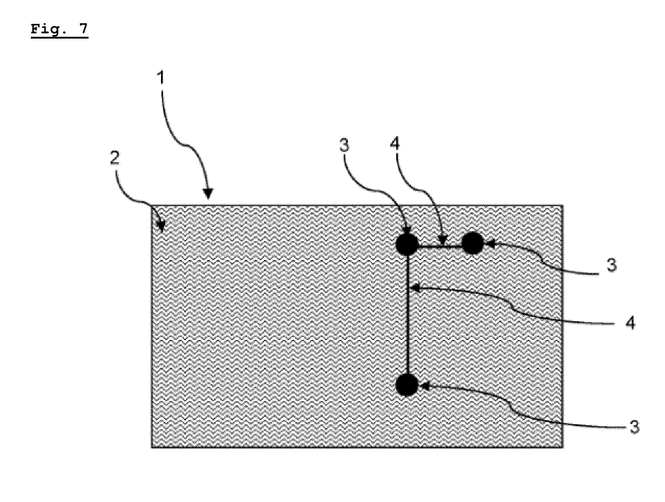

FIG. 6 and FIG. 7 show information carriers with conductor paths,

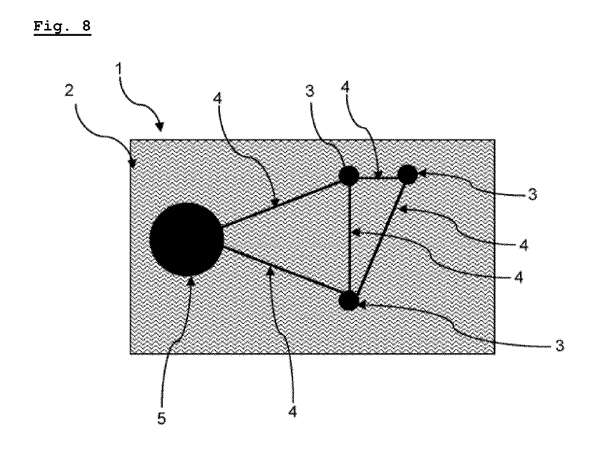

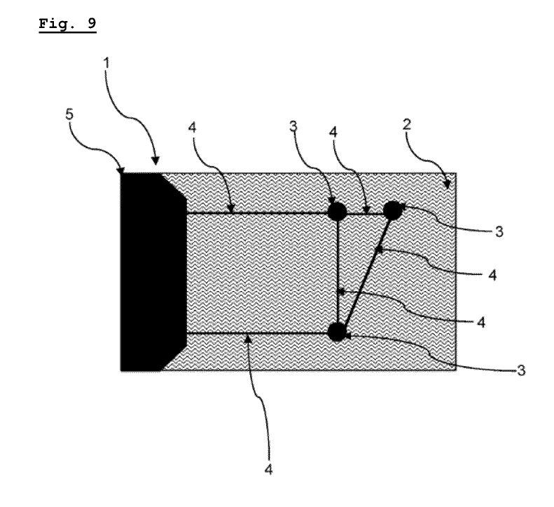

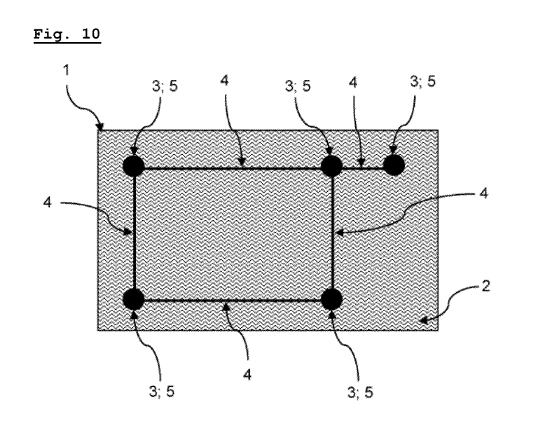

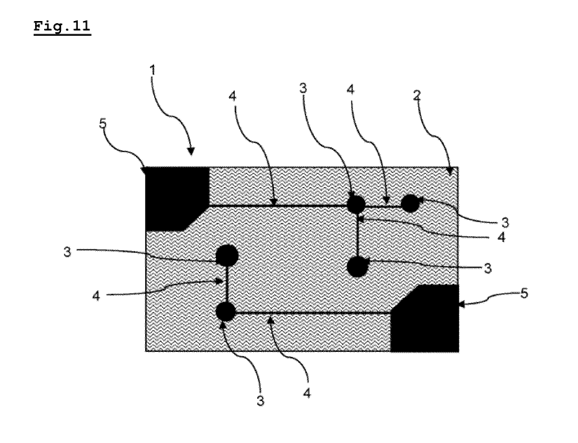

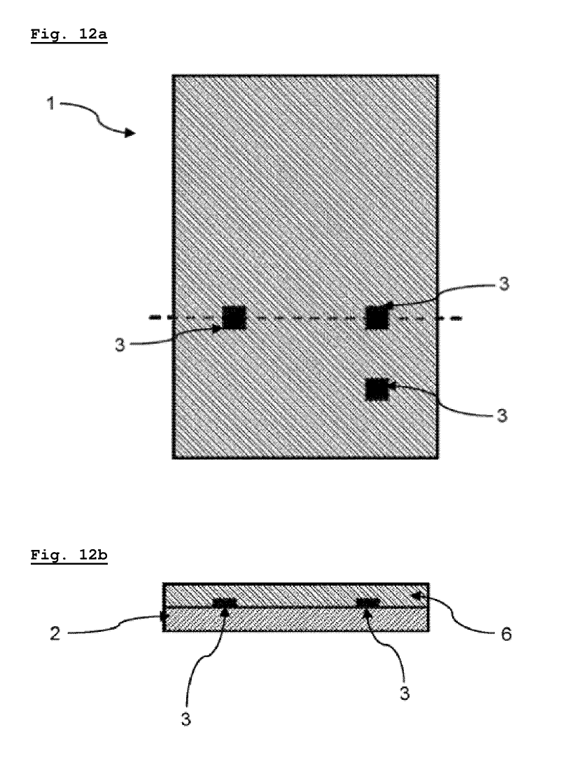

FIG. 8 to FIG. 11 show information carriers with conductor paths and coupling surface(s),

FIG. 12a and FIG. 12b show information carriers with a cover layer in a sectional illustration,

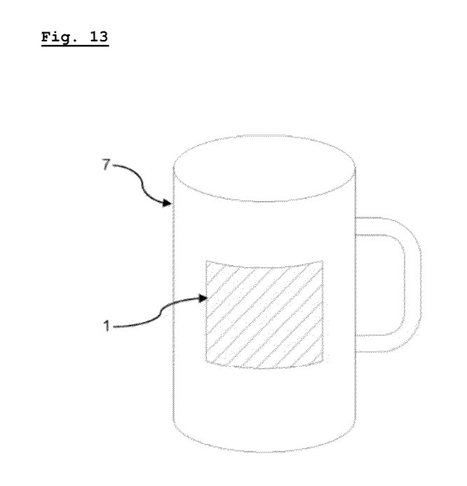

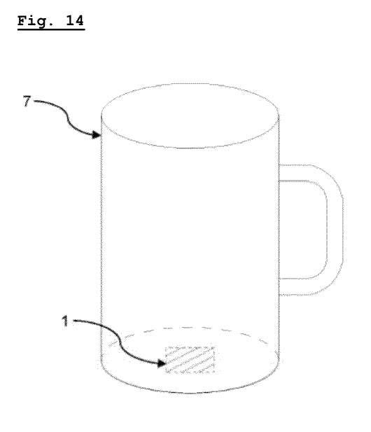

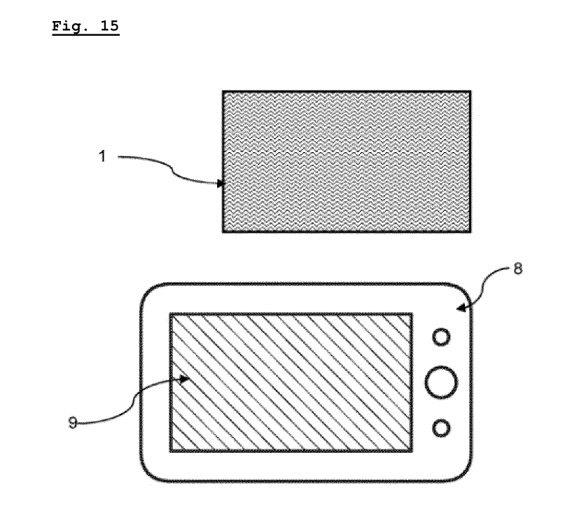

FIG. 13 and FIG. 14 show information carriers on an article,

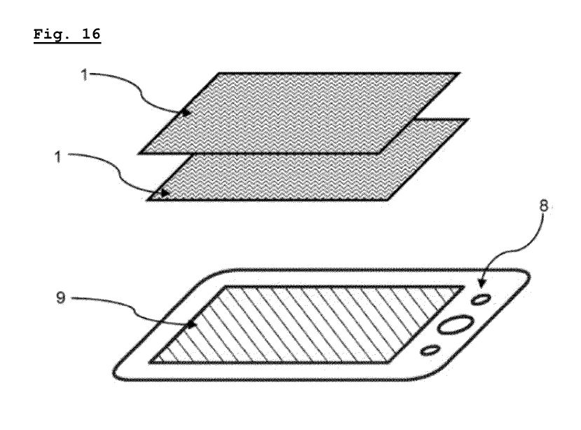

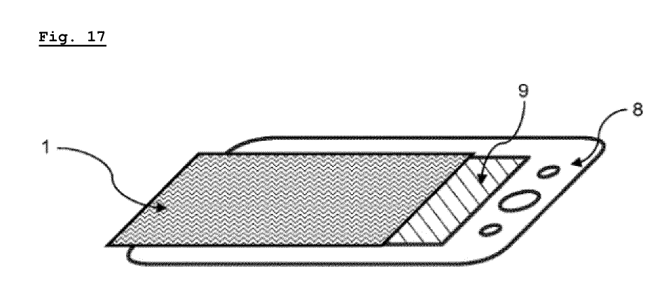

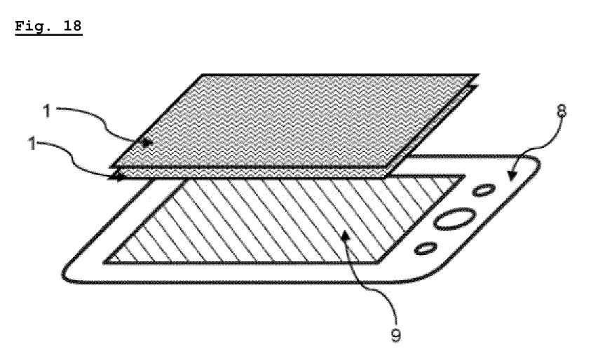

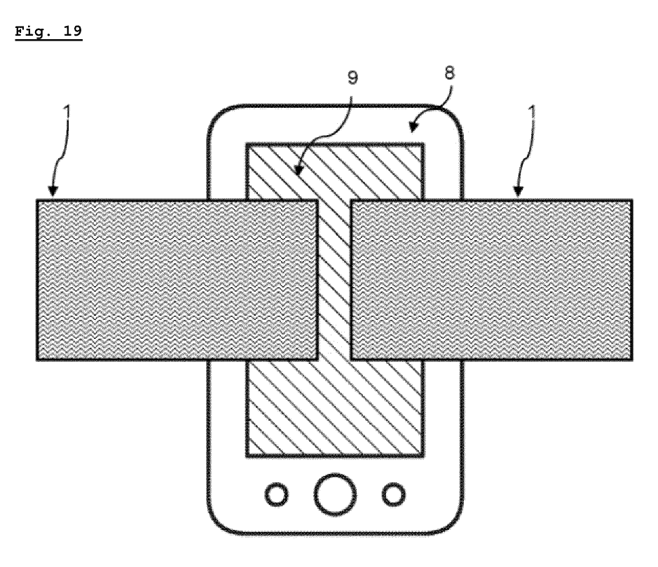

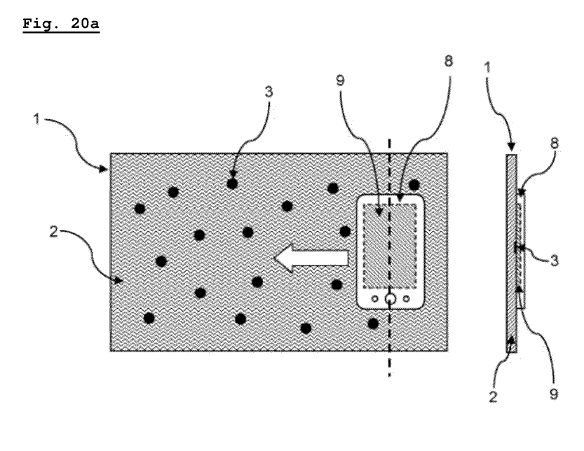

FIG. 15 to FIG. 20 show the interaction of one or a plurality of information carriers with an area sensor,

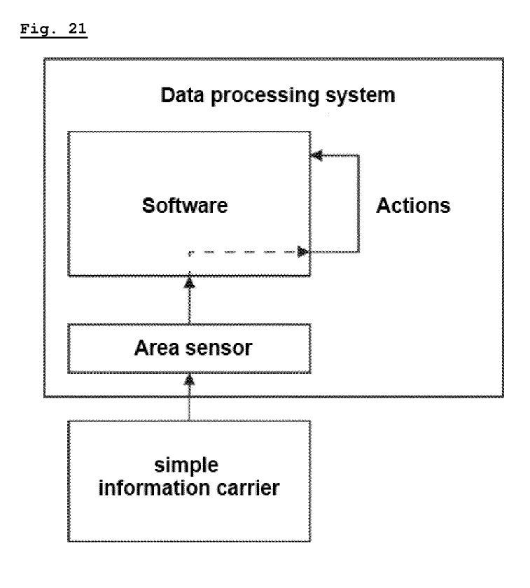

FIG. 21 to FIG. 25 show preferred applications of an information carrier,

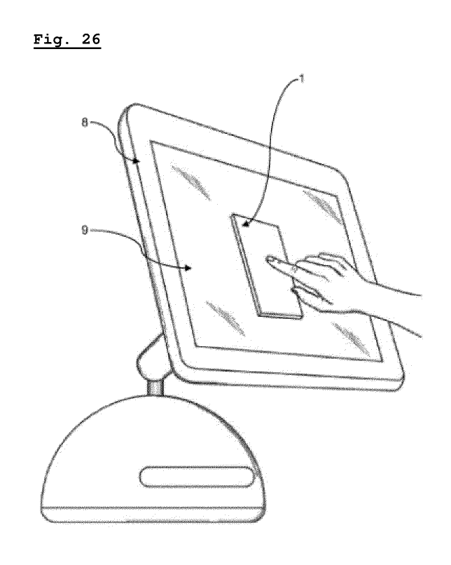

FIG. 26 to FIG. 28 show the use of an information carrier on a device having an area sensor,

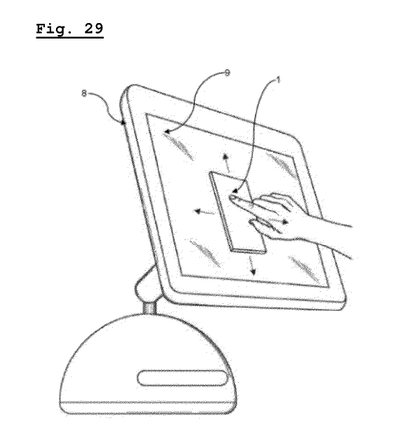

FIG. 29 shows the movement of an information carrier on a device,

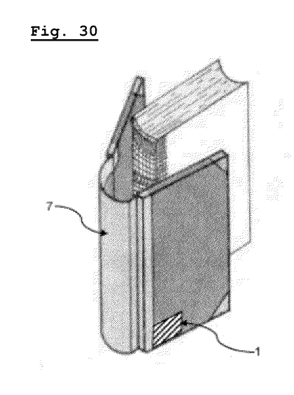

FIGS. 30 to 34 show preferred uses of an information carrier,

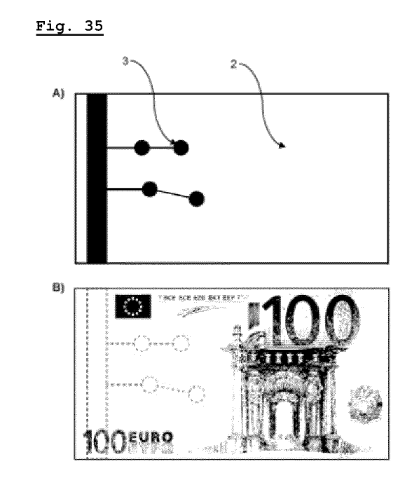

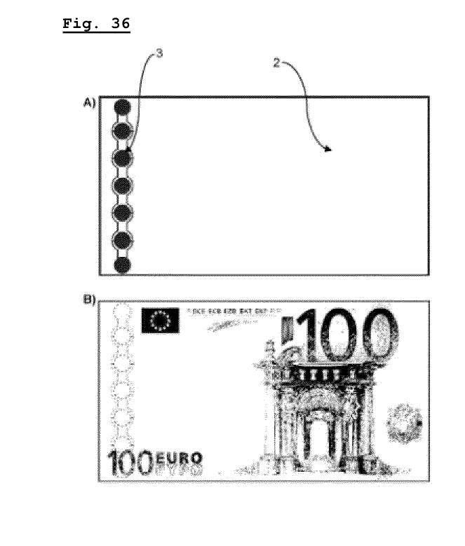

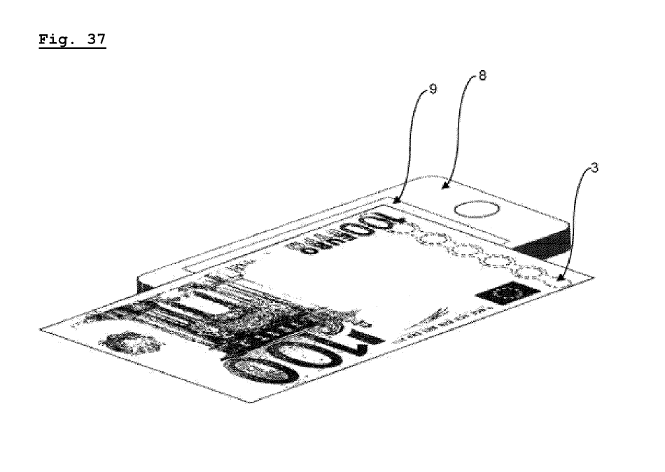

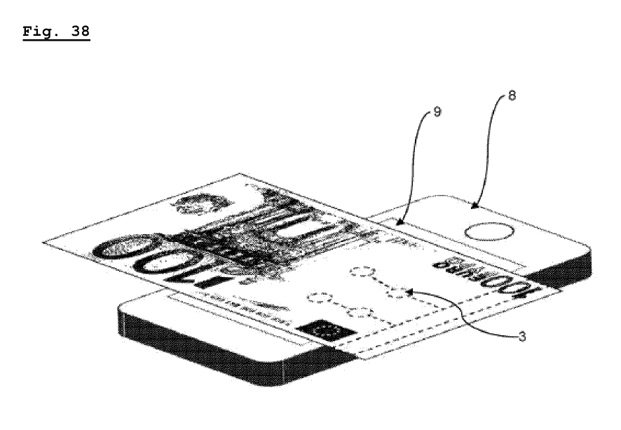

FIGS. 35 to FIG. 38 show the use of an information carrier as a security feature on a bill.

FIG. 1 to FIG. 4 show top views of preferred configurations of an information carrier 1. An information carrier 1 consists substantially of a substrate 2 having at least one electrically conductive layer applied at least in certain areas, wherein the said layer is the touch structure 3. The substrate 2 is a carrier and preferably consists of a plastic, a paper, a card board, a wooden material, a composite material, glass, ceramics, textiles, leather or a combination thereof. The electrically conductive touch structure 3 is applied in certain areas on the substrate 2.

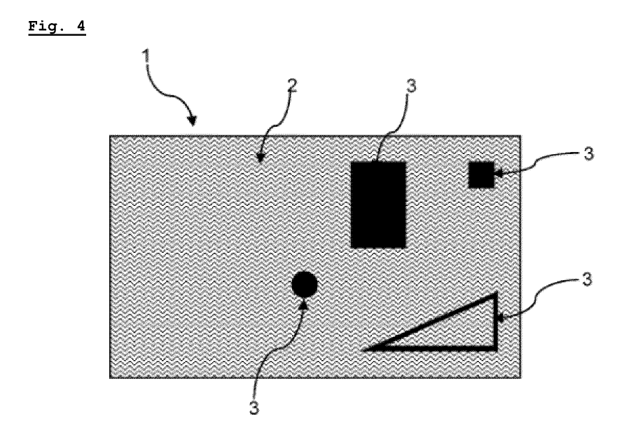

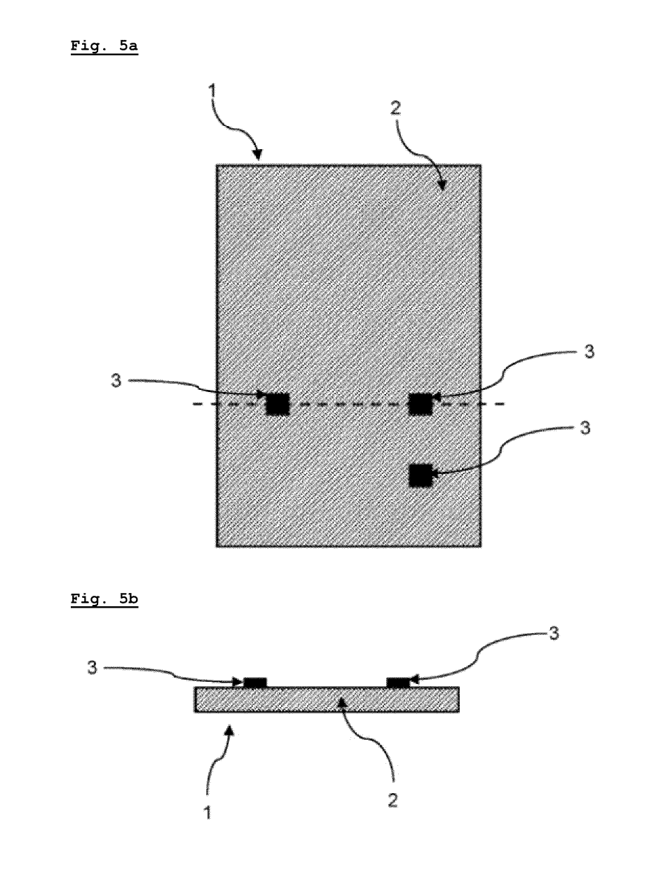

The touch structure 3 can be applied onto the substrate 2, for example, in the form of circles and/or rectangles. Advantageously, the touch structure 3 can also be represented with different geometrical figures (FIG. 1, 2, 3), wherein they can also be combined with each other (FIG. 4).

FIG. 5a and FIG. 5b show an information carrier 1 in a schematic sectional illustration. The elevated touch structure 3 in FIG. 5b serves for a better illustration. Depending on the production method for the touch structure 3, the latter can be embossed (e.g. screen printing), flush with the surface (e.g., offset printing) or even recessed (e.g. hot stamping) with respect to the surrounding substrate.

FIG. 6 and FIG. 7 show information carriers 1 with conductor paths 4. The subareas of the touch structure 3 can advantageously be smaller, equal to (FIG. 6) or larger (FIG. 7) than the conductor paths 4. In further embodiments (FIG. 8, 9, 10, 11), at least one further subarea of the electrically conductive layer (the touch structure 3) is located as a coupling surface 5 on the substrate 2. The individual subareas of the touch structure 3 are preferably connected to each other in an electrically conductive manner via conductor paths 4. Advantageously, the touch structure 3 and the conductor paths 4 are formed from the electrically conductive layer.

FIG. 12a and FIG. 12b show an information carrier 1 with a cover layer 6 in a schematic sectional illustration. On the substrate 2 and the electrically conductive touch structure 3 there is at least one cover layer 6 so that a compact information carrier 1 is obtained, and the touch structure 3 is in particular not damaged and is not visible from the outside. The cover layer 6 can also be configured as a cover plate.

FIG. 13 and FIG. 14 show an information carrier 1 on an article 7. Advantageously, the information carrier 1 according to the invention can be applied onto an article, for example, a cup. Through this, advantageously, digital information can be sent in a fast and simple manner to a buyer of an article by means of the information carrier 1. The information carrier 1 is preferably printed on the article 7, wherein the information carrier 1 can be applied onto an even or uneven surface.

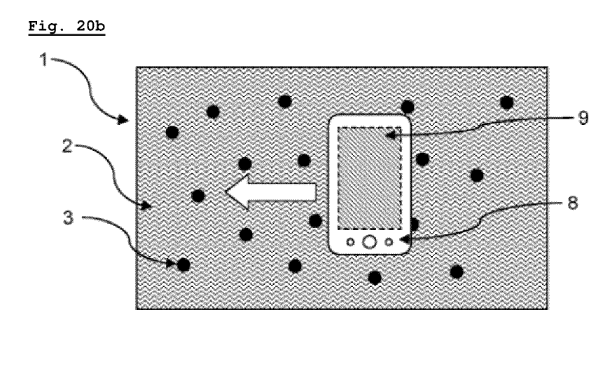

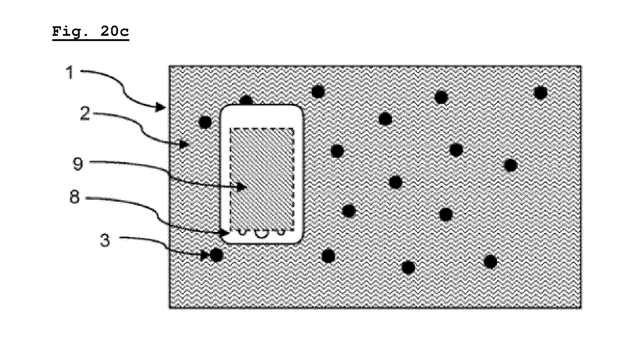

FIG. 15 to FIG. 20 show an interaction of one or a plurality of information carriers 1 with an area sensor 9. The information carrier 1 together with the information stored thereon can be brought in contact with a device having an area sensor 8. The device having an area sensor 8 is preferably a data-processing device. For example, the information carrier 1 may contact the area sensor 9 only in certain areas. It can also be preferred that the information carrier 1 is not laid onto the area sensor 9, but is moved across the latter. Through a different way of contacting and approaching, preferably, a different event can be triggered on the area sensor 9. Moreover, a plurality of information carriers 1 can interact with the area sensor 9. In FIG. 20, the area sensor 9, i.e., the device 8 comprising the area sensor, is moved across an information carrier 1, wherein the information carrier 1 has to contact or approach the area sensor 9 several times at different positions so that the complete information of the information carrier 1 becomes readable. Hereby, larger amounts of information can be stored in the information carrier 1 because now the information carrier 1 can be larger than the area sensor 9. Reading the information by the device having the area sensor 8 can preferably be implemented through wiping movements.

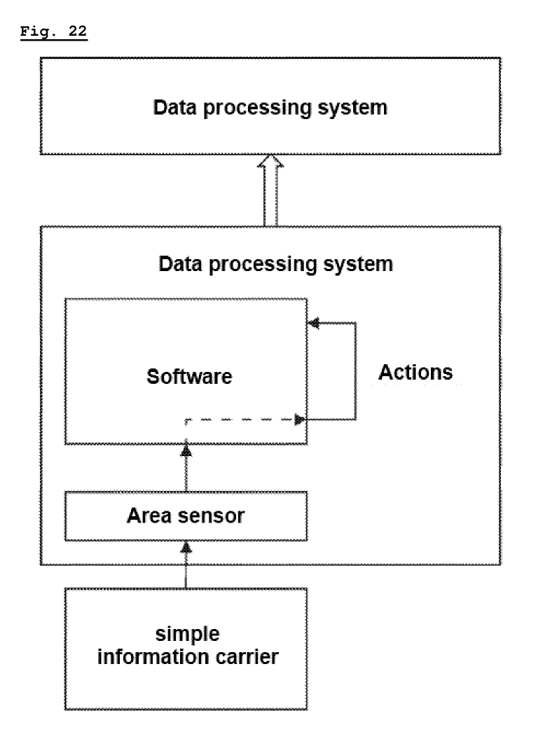

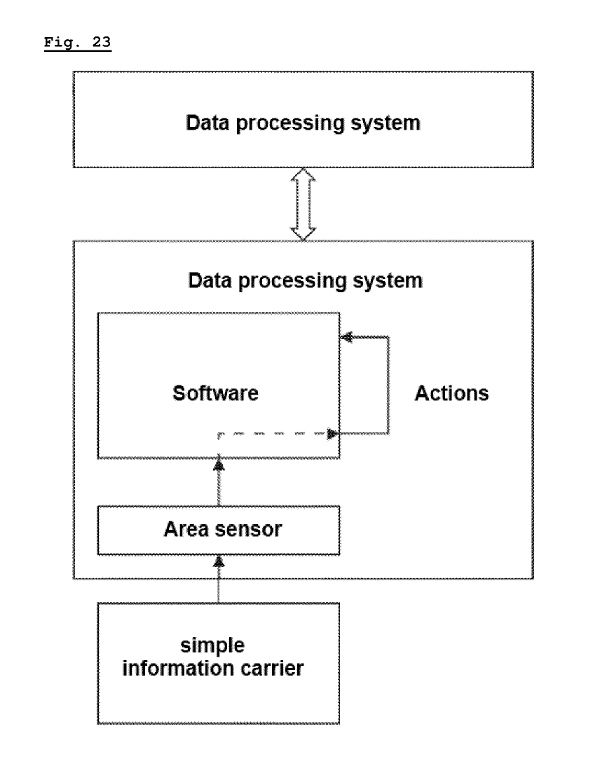

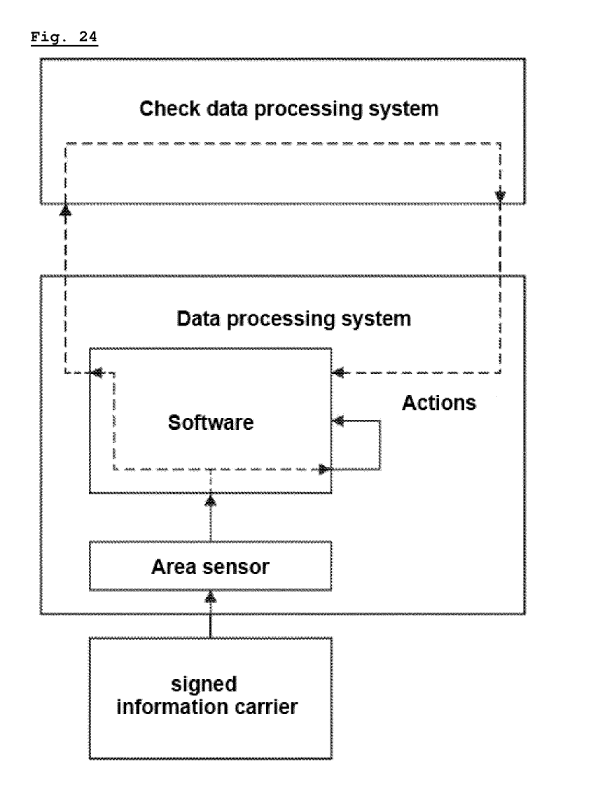

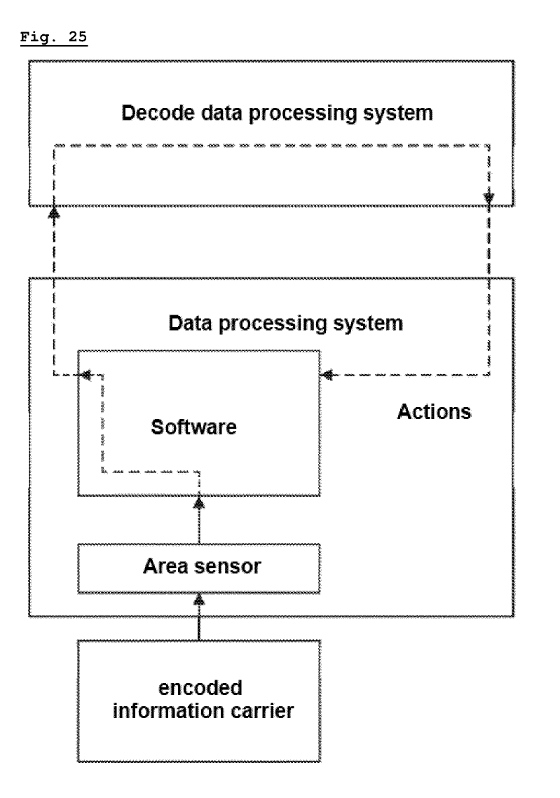

FIG. 21 to FIG. 25 show preferred applications of an information carrier. The information carrier can be utilized according to FIG. 21 as a simple information carrier that interacts with an area sensor, whereby preferably an event is triggered. The event, in turn, triggers actions such as, for example, activating and/or terminating an application, changing numeric values and/or texts, manipulating graphics, changing databases or gaining access to information technology services, without being limited thereto. Moreover, according to FIG. 22, it is possible via the areas sensor, for example, in the form of a capacitive touchscreen of a device, to influence the program sequence of a data processing system of the device itself. The triggered action can be one-sided or two-sided, i.e., an action can be triggered which acts on an external data processing system, wherein the latter, in turn, acts on the data processing device (see FIG. 23). Furthermore, the information carrier can be configured as a signed information carrier (see FIG. 24), preferably resulting in an interaction between the data processing device, a data network and a data processing system. Thus, for example, the signed information carrier can be checked and verified via the internet. By means of the system according to the invention, access and/or use of a data processing system is enabled. For this, the device is connected via a data network to a data processing system by means of the information carrier. After checking the signature in the data processing system, the access is established via the device. Furthermore, according to FIG. 25, the information carrier can also be encoded, wherein the latter interacts in particular with a device, a data network, and a data processing system. Through the area sensor, utilizing a data processing system is enabled. For this, the device is connected to the data processing system by means of a data network. After a positive check of the information carrier in the data processing system, the access is established via the device.

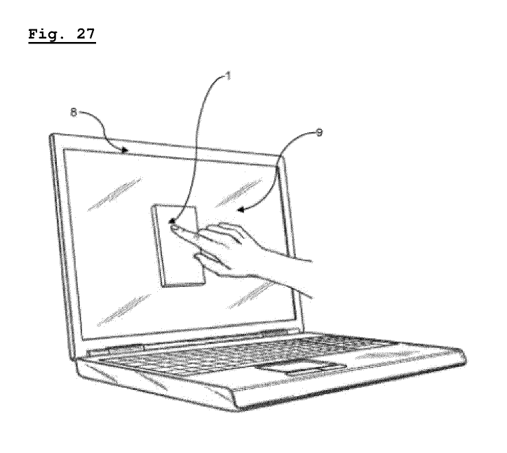

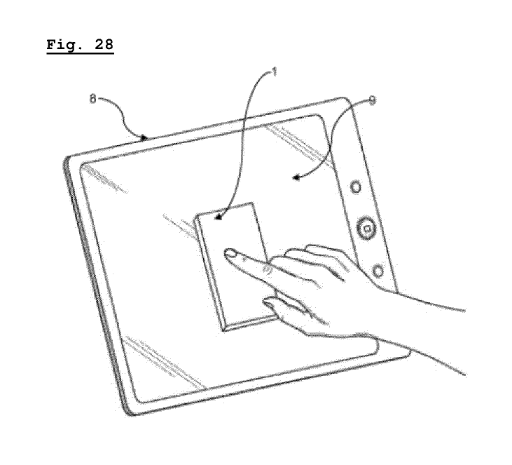

FIG. 26 to FIG. 28 show the use of the information carrier 1 on different devices 8, wherein all devices 8 have an area sensor 9, in particular a capacitive touchscreen. The information carrier comprises substantially a substrate with at least one electrically conductive layer that is applied in certain areas, wherein said layer is the touchscreen. The substrate is a carrier and preferably consists of a plastic, a paper, a card board, a wooden material, a composite material, glass, ceramics, textiles, leather or a combination thereof. The electrically conductive touch structure is applied onto the substrate in certain areas. According to the invention, a touch structure is a layer from electrically conductive material applied in a structured manner. The information carrier 1 is preferably produced by means of a transfer film method through which a very cost-effective information carrier 1 can be produced. The information carrier 1 can be used, for example, as a coupon. The recipient of the coupon—of the information carrier 1—brings the information carrier 1 in contact with a device having an area sensor 8. This can be, for example, a PC (see FIG. 26), a laptop (FIG. 27) or a tablet PC (FIG. 28). A capacitive area sensor is in particular a physical interface for acquiring electrical capacitances and/or capacitance differences within subareas of a defined area. Devices containing area sensors comprise, for example, smartphones, cell phones, displays, tablet PCs, tablet notebooks, touchpad devices, graphics tablets, television sets, PDAs, MP3 players, trackpads and/or capacitive input devices. Such an area sensor, for example, can also be an integral part of input devices as a touchscreen, touchpad or graphics tablet. Touchscreens are also known as tactile screen or touch-sensitive screen. Such input devices are used, amongst others, in smartphones, PDAs, touch displays or notebooks. The information carrier 1 can be brought in contact with the area sensor 9 or can approach the same in order to thereby trigger an event. The event can involve, for example, that the information carrier 1 triggers a program on the device 8 which, for example, displays a certain webpage to the recipient of the coupon. The recipient receives a rebate over a defined amount and can use this rebate for products that are presented on the webpage. Advantageously, the interaction or the recognition of the information carrier 1 by the device 8 such as, for example, a PC, laptop or tablet PC, takes place very rapidly.

FIG. 29 shows a movement of an information carrier at an area sensor. The information carrier 1 can be brought in contact with an area sensor 8 in certain areas or can at least be moved close to the area sensor 9. On the substrate of the information carrier 1 there is at least one electrically conductive layer that is applied in certain areas, wherein at least one area of the electrically conductive layer is a subarea. In the meaning of the invention, the subarea(s) are also designated as touch structure. The shape, orientation, quantity, alignment, distance and/or position of the touch structure or the subareas thereof preferably form the information so that by positioning the information carrier 1 on the area sensor 9 at least in certain areas or via a relative movement of at least one area of the information carrier 1 with respect to the area sensor 9, at least one event is triggered. In the meaning of the invention, positioning the information carrier 1 on the area sensor 9 in certain areas means that in particular one area of the information carrier 1 is in contact with at least one area of the area sensor 9. Preferred movements of the information carrier 1 at the area sensor 9 are indicated as arrows in FIG. 29. The movement can take place in all directions on the area sensor 9—such as, for example, horizontally or vertically—and can be carried out, for example, in the form of a curve, a circle or a straight line. By contacting or approaching, a capacitive interaction between the information carrier 1 and the area sensor 9 is achieved, and the touch structure of the information carrier 1 becomes evaluable for a data processing system connected to the area sensor 9 and thereby can trigger events associated with the information carrier 1.

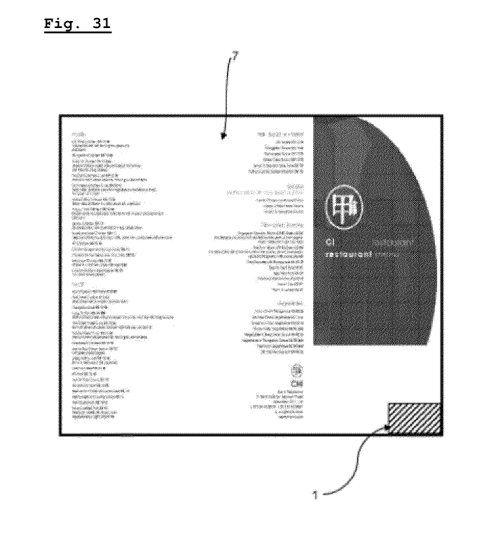

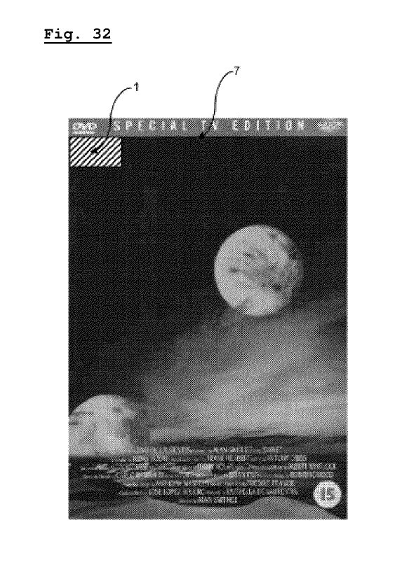

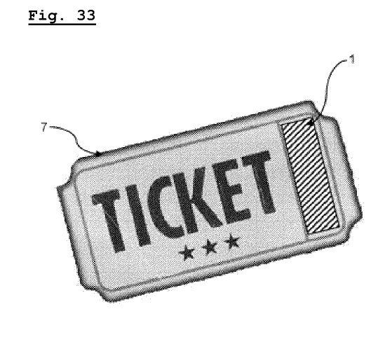

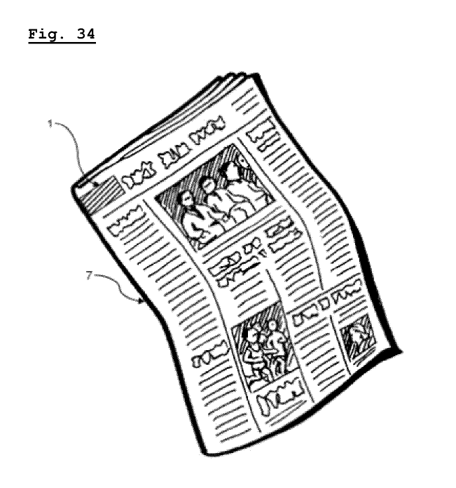

FIG. 30 to FIG. 34 show preferred applications of an information carrier. The information carrier 1 can be deployed and used in a versatile manner. The information carrier 1 can be attached on different articles 7 or can be printed thereon. For example, it is preferred to attach the information carrier 1 on an article 7 such as, for example, a book (see FIG. 30). The information carrier can also be attached in the book cover or at a different location in the book, wherein the information carrier 1 can be printed onto the book or can be attached thereon in a different manner. A person interested in the book can bring a device having an area sensor, for example a smartphone, in contact with the information carrier 1 or close thereto, whereby an event and preferably an action is triggered on the smartphone. The action can direct an internet-capable smartphone, for example, to a webpage on which a free sample of the book is available for the interested person. The interested person thus can inform himself/herself about the content of the book prior to buying it. The interested person or potential buyer of the book can also find information about the author of the book by means of the information carrier 1, and can be informed about further works of this author. In FIG. 31, a further preferred use of the information carrier 1 is illustrated. Here, the information carrier 1 is applied on another article 7, namely a menu. The information carrier 1 can be printed on the menu or can be attached thereon in a different manner. When dining in a restaurant, the menu is presented to a visitor. The visitor can select a dish from the menu and, in addition, can read the information carrier 1 applied on the menu with a device having an area sensor, for example, with his/her smartphone. For this, he/she brings the device in contact with the information carrier or in the proximity thereof, whereby, e.g., an event and an action is triggered on the smartphone. The action can involve that further information about the selected dish is displayed to the visitor. The information can comprise ingredients, further substances or allergy information. Also, where appropriate, the visitor can view the recipe for preparing the dish and can save it on his/her device, for which the restaurant may charge a fee, for example. Also, by means of the information carrier 1, the visitor can be informed about events that take place in the restaurant. Advantageously, the events in which the visitor is interested can be saved directly in a calendar application on the smartphone. Moreover, the address of the restaurant is advantageously entered into an address management application on the smartphone. FIG. 32 shows a further preferred use of the information carrier 1. Here, the information carrier 1 is applied onto an article 7, for example, a DVD cover. Advantageously, the information carrier 1 can be printed on different packaging or can be attached thereon in a different manner. An interested person who wants to acquire the DVD, can bring a device having an area sensor, for example, his/her smartphone, in contact with the information carrier 1 or can bring it close thereto. The information carrier 1 triggers an event or an action on the smartphone, whereby the interested person receives information about the product. For example, by means of the information carrier 1, an internet-capable smartphone can be directed to a webpage on which the interested person can watch a trailer of the movie that he/she wants to buy. Information about the actors, available languages, etc., is available to the interested person. If the information carrier 1 is applied onto a music CD, the interested person, after reading the information carrier 1 by means of a smartphone, can listen to free samples of the music CD. It can also be advantageous that the information carrier 1 is attached on or in the packaging in such a manner that the information carrier becomes accessible to the buyer only after the purchase of the product. The information carrier 1 then gives the buyer access to additional material which, for example, can be viewed via a webpage. Also, merchandising products for the purchased movie can be offered on the webpage. FIG. 33 illustrates a further preferred use of the information carrier 1. The information carrier 1 is attached on an article 7, for example, a ticket. The ticket can be, e.g., a concert ticket, a theater ticket or a movie ticket by means of which a person gains access to the corresponding show. On the one hand, the information carrier 1 can be used as access authorization or authenticity certificate so that the information carrier 1 is read by a reader or a device having an area sensor, and allows a person access to the show only after a positive validation. On the other hand, the information carrier 1 can be used for the purpose that the person brings a device having an area sensor in contact with the information carrier 1 or in the vicinity thereof, and an event or an action is triggered on the device. The action can involve, for example, that the person gains access to a webpage on which recordings of the concert or information about the musicians can be viewed. Moreover, by means of the information carrier 1, the dates of the concert can be automatically entered into a calendar application and the address of the venue can be automatically entered into an address management application. Thus, for example, the way to the venue can be displayed on the smartphone to the person. FIG. 34 shows a further preferred use of an information carrier 1 that is applied onto an article 7, wherein the article can be a daily newspaper. The information carrier 1 can be printed onto a newspaper or, e.g., can be enclosed in it. A buyer of the newspaper can read the information carrier 1 with a device having an area sensor, whereby further information is accessible to the buyer, for example. The buyer gains access to a webpage on which, e.g., videos relating to the articles or interviews can be watched. Furthermore, it is advantageous if the information carrier 1 functions as a coupon. This means, the buyer of the newspaper can read the information carrier 1 and possibly receives a trial subscription for the newspaper. The information carrier 1 can also be used for advertising purposes in that further information carriers 1 containing advertisement for third parties are enclosed to the newspaper. For example, the buyer of the newspaper can read an information carrier 1 with a smartphone and gains access to a webpage of the third party on which the products of the latter are offered. If appropriate, the address of a store of the third party is stored directly on the smartphone. Moreover, offers of goods of the third party can be communicated to the buyer by means of the information carrier 1. It can also be advantageous if a potential buyer can read the information carrier 1 prior to buying the newspaper and receives by means of a smartphone an overview of the articles contained in the newspaper. An extract of the newspaper can already be offered to the buyer upon visiting a kiosk, prior to buying a newspaper.

FIG. 35 to FIG. 38 show a use of the information carrier as a security feature on a bill. The information carrier 1, for example, can be implemented in a banknote, i.e., a bill. Here, the paper of the bill can function as a substrate 2 on which the information carrier 1 or the touch structure 3 is applied. Thus, the information carrier can serve as a security feature which is not visible for a user of the bill. However, it can also be preferred that the touch structure 3 is printed on the bill in such a manner that it is completely or partially visible for a user, which shows the user that the bill comprises numerous security features. Accordingly, as a visible copy protection, this can serve as a deterrent. The information carrier 1 can be read by means of a reader or an area sensor 9 so that hereby the authenticity of the bill is verified. The area sensor 9 (e.g. a touchscreen) can be an integral part of an electrical device 8 having an area sensor 9. Moreover, adequate readers or applications on a device 8 comprising an area sensor can be made available, for example, to visually impaired persons, whereby verifying and also counting of bills is made possible. In this connection, the information carrier 1 on the bill could encode the value of said bill. The bill with the information carrier 1 is placed onto the area sensor 9 or slid across it by means of a movement whereby the information carrier 1 is read by the area sensor 9 and the data are further processed (e.g. for verifying authenticity).

### REFERENCE LIST

1 Information carrier
2 Substrate
3 Touch structure
4 Conductor path
5 Coupling surface
6 Cover layer
7 Article
8 Device having an area sensor
9 Area sensor

1. A capacitive information carrier,
comprising
a non-conductive substrate, and
at least one electrically conductive touch structure, wherein
on the electrically non-conductive substrate the at least one electrically conductive touch structure is arranged.

2. A capacitive information carrier produced through a transfer film method, comprising the following:
a. providing a transfer film on a roll, wherein the transfer film comprises a carrier film and an electrically conductive transfer layer placed thereon at least in certain areas,
b. providing an electrically non-conductive substrate,
c. providing an adhesive,
d. applying the adhesive according to c) in a structured manner onto the substrate and/or the transfer film,
wherein on the electrically non-conductive substrate, at least in certain areas, an electrically conductive layer is arranged as a touch structure.

3. A method for producing a capacitive information carrier, comprising:
a. providing a transfer film on a roll, wherein the transfer film comprises a carrier film and an electrically conductive transfer layer placed thereon at least in certain areas,
b. providing an electrically non-conductive substrate,
c. providing an adhesive,
d. applying the adhesive according to c) in a structured manner onto the substrate and/or the transfer film,
wherein on the electrically non-conductive substrate, at least in certain areas, an electrically conductive layer is arranged as a touch structure.

4. (canceled)

5. The capacitive information carrier according to claim 1,
wherein
on an electrically non-conductive substrate at least one electrically conductive touch structure is arranged which simulates the arrangement and/or properties of fingertips.

6. The capacitive information carrier according to claim 5,
wherein
the adhesive is an electrically conductive adhesive.

7. The capacitive information carrier according to claim 1,
wherein
at least the touch structure is covered with a further layer.

8. The capacitive information carrier according to claim 7,
wherein
the further layer covering the touch structure is a paper layer, a film layer, a paint layer, a lacquer layer and/or combinations thereof.

9. The capacitive information carrier according to claim 1,
wherein
on the substrate at least one coupling surface is arranged which is connected to the at least one touch structure via at least one conductor path, and/or a part of the touch structure is a coupling surface.

10. The capacitive information carrier according to claim 1,
wherein
said information carrier has at least one cover layer which completely or partially covers the substrate.

11. The capacitive information carrier according to claim 1,
wherein
the information carrier is connected to an article, or the article itself serves as a substrate.

12. The capacitive information carrier according to claim 1,
wherein
the applied touch structure is alterable in certain areas in terms of its structuring by via additive and/or subtractive methods, preferably by inkjet methods and particularly preferred by laser methods.

13. A system for acquiring information, comprising:
a. at least one capacitive information carrier according to claim 1,
b. at least one capacitive area sensor and
c. a static and/or dynamic contact between a. and b. takes place, and through this, a capacitive interaction is achieved.

14. The system according to claim 13,
wherein
through the capacitive interaction, the touch structure of the information carrier is evaluable for a data processing system connected to the area sensor, and said data processing system can trigger events associated with the information carrier.

15. The system according to claim 13,
wherein
the area sensor and/or a device containing the area sensor comprises capacitive touchscreens and/or touchpads and is selected from the group consisting of smartphones, cell phones, displays, tablet PCs, tablet notebooks, touchpad devices, graphics tablets, television sets, PDAs, MP3 players, trackpads and capacitive input devices.

16. The system according to claim 13,
wherein
at least one information carrier is in contact with at least one area sensor at least in certain areas.

17. The system according to claim 13,
wherein
the area sensor, in a movement relative to the information carrier, progressively receives complete or partial information from the information carrier.

18. The system according to claim 1,
wherein
a plurality of information carriers are read in combination, in particular next to each other and/or one above the other and/or in chronological succession.

19. A method for acquiring information, comprising
a. providing at least one capacitive information carrier according to claim 1, said information carrier having an electrically non-conductive substrate which comprises at least one electrically conductive touch structure and at least one capacitive area sensor,
b. bringing at least one information carrier in contact with the at least one area sensor, wherein the contact can be static and/or dynamic, and
c. triggering a capacitive interaction between the area sensor and the information carrier, wherein through the capacitive interaction, the touch structure of the information carrier becomes evaluable for a data processing system connected to the area sensor and can trigger events associated with information carrier.

20. The method according to claim 19,
wherein
the information carrier is assigned to a dataset in the data processing system and the dataset remains constant.

21. The method according to claim 19,
wherein
the information carrier is assigned to a dataset in a data processing system and the dataset changes.

22. The method according to according to claim 19,
wherein
the information carrier in connection with the area sensor is assigned via the touch structure to an action of a data processing system or triggers said action.

23. The method according to claim 19,
wherein
at least two information carriers are combined, and through the combination, an event is triggered.
